(19) United States
(12) Patent Application Publication
(10) Pub. No.: US 2005/0285101 A1
(43) Pub. Date: Dec. 29, 2005

(54) Formation of ordered thin films of organics on metal oxide surfaces

(76) Inventors: Eric Hanson, San Diego, CA (US); Jeffrey Schwartz, Princeton, NJ (US); Norbert Koch, Berlin (DE); Jing Guo, Princeton, NJ (US); Ian Gregory Hill, Halifax (CA); Joe McDermont, Princeton, NJ (US)

Correspondence Address: HELLER EHRMAN LLP, 275 MIDDLEFIELD ROAD, MENLO PARK, CA, 94025-3506, US

(21) Appl. No.: 11/148,859

(22) Filed: Sep. 6, 2005

Related U.S. Application Data
(60) Provisional application No. 60/577,766, filed on Jun. 8, 2004.

(51) Int. Cl. H01L 29/08; H01L 51/40

(52) U.S. Cl. 257/40; 438/99

(57) ABSTRACT

Provided herein is a method for altering an electronic property of a structure comprising an oxide surface or an oxide surface in electronic communication with the structure, the method comprising providing a covalently-bound film comprising at least one organic acid residue on a portion of the oxide surface so that at least one of the following properties of the structure is modified: (a) the charge carrier injection barrier properties; (b) the charge conductivity properties; (c) the charge transport properties; (d) the work function properties; (e) the sub-threshold slope; and (f) the threshold voltage.

This application claims the benefit of U.S. Provisional Application No. 60/577,766, filed Jun. 8, 2004, entitled “Self-Assembled Monolayers on Metal Oxide Surfaces” the disclosure of which is incorporated herein in its entirety.

### FIELD OF THE INVENTION

A new method is described for surface modification of a transparent conductive oxide with an electroactive organic film to enhance hole injection in a device. The film may comprise a monomer, an oligomer or a polymer, and the devices that form from these organic groups may include an organic light emitting diode (OLED) or polymer light emitting diode (PLED). The semiconductor film is covalently bound to the transparent conductive oxide, such as indium tin oxide (ITO), to ensure strong adhesion and interface stability, and reduction of the hole injection barrier in these devices was obtained. In one aspect, the reduction of the hole injection barrier was accomplished by formation of a charge transfer complex within the film.

Definitions:

“Alkyl” means a straight or branched, saturated or unsaturated aliphatic radical, and where noted, the alkyl has the number of carbon atoms depicted. An alkyl group may comprise a heteroatom, such as an oxygen, nitrogen or sulfur inserted within or in the chain of the alkyl group. Alkyl groups include straight chain and branched C₁₋₂₀alkyl groups, such as C₁₋₁₀alkyl groups. Typical C₁₋₁₀alkyl groups include methyl, ethyl, n-propyl, isopropyl, n-butyl, sec-butyl, iso-butyl, n-pentyl, 2-pentyl, 3-pentyl, n-hexyl, n-heptyl, n-octyl groups, and the like.

“Arene” or “acene” or “aryl” means a monocyclic or polycyclic ring wherein at least one ring is an aromatic ring, or when fused (acenes) with one or more rings forms an aromatic ring that is connected with one or more aromatic, or non-aromatic rings, and the polycyclic ring may be linearly or angularly fused, or combinations thereof. Arenes as used in the art may also be referred to as acenes. Such covalently linked rings include, for example, biaryls. Such polycyclic rings that are linked by one or more covalent bonds may be referred to as polyarenes or polyaryls. Where one or more ring atoms of the arene is not a carbon atom (e.g., a N, S, P or O), the arene may be termed a heteroarene or heteroaryl. The arenes may also be “heteroarenes”, wherein different rings such as a heterocycle (or heteroaryl), aryl, saturated or partially saturated ring are linked in various different permutations. Examples of such heteroarenes include phenyl-thiophenyl-phenyl-thiophenyl. Arenes may be non-functionalized (un-substituted) or may be functionalized with one or more substituents.

Non-exclusive examples of such arenes, acenes or aryls include (without depicting the unsaturation and or the heteroatoms): 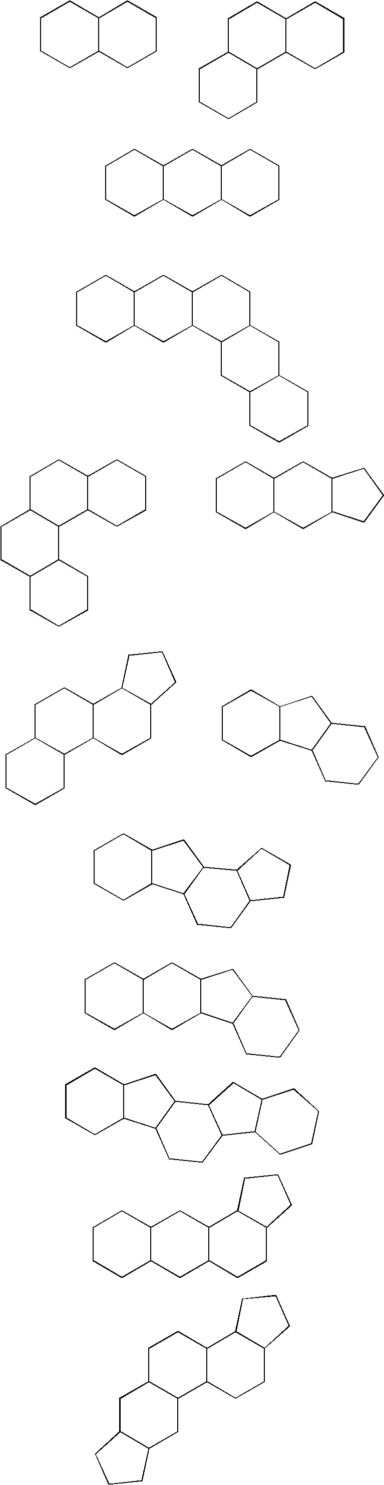 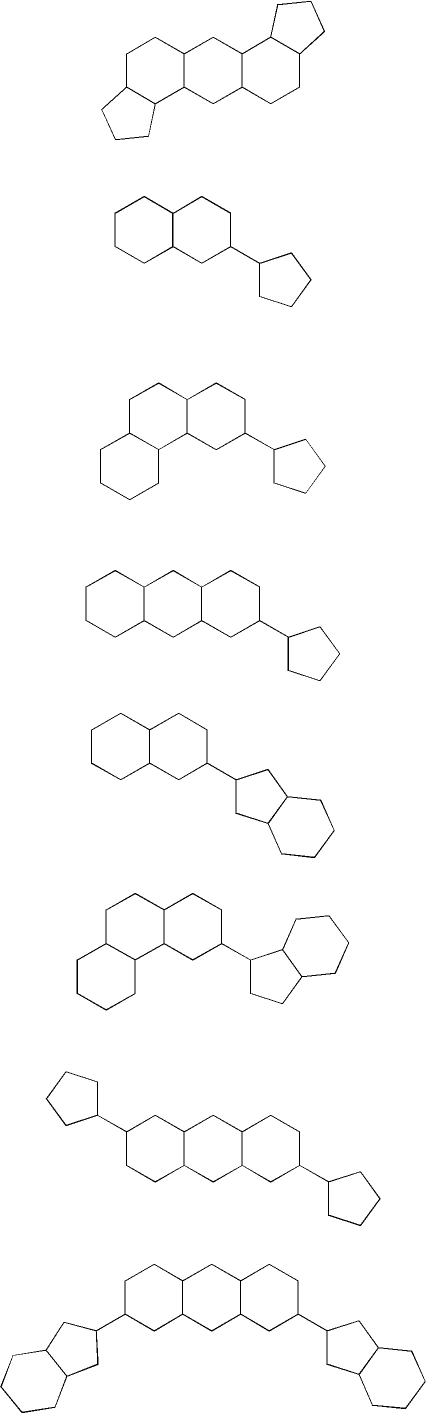 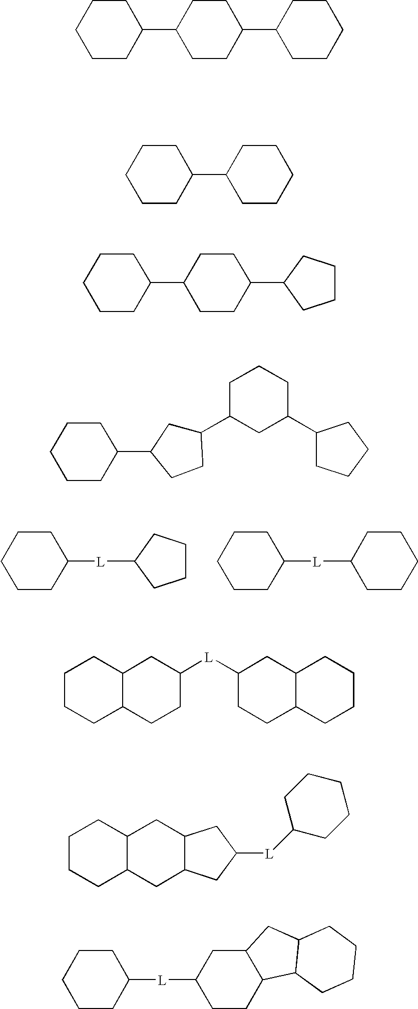
wherein L is a linking group comprising 1, 2, 3, 4, 5 or 6 chain atoms selected from the group consisting of C, O, N, S, Si or P, and the linking group may be saturated, partially saturated or unsaturated. Examples of the linking group include, for example, —O—, —S—, —NH—, —NR—, —SiRR′—, —CO—, —COO—, —OCO—, —CONR—, —NRCO—, —S—CO—, —COS—, —CH═CH—, —CF═CH—, —CF═CF—, —CH═C(CN)—, —CH═CH—CH═CH—, —C≡C—, and the like.

“Dense” as used herein means the close packing of the molecules having a molecular cross-sectional area of less than about 150 Å²/molecule. In certain aspects, the molecular cross-sectional footprint area is less than about 110 Å²/molecule, or less than about 100 Å²/molecule, preferably about 40-50 Å²/molecule, preferably less that about 30-40 Å²/molecule, and more preferably less than about 26-30 Å²/molecule. In certain variations, the molecular cross-sectional area is less than about about 23-26 Å²/molecule. More specifically, the term “density” as used herein means the average distance between molecules in the film, such as a self-assembled film, relative to that observed for the crystalline (fully dense) form of the corresponding parent molecular system. With respect to the ability to enhace hole injection in a device as disclosed herein, the activity may be observed when the density of the film is in the range of about 5-10%, 1-25%, 25-50%, 50-75% or 75-100% of the density of the crystalline form of the film, such as the crystalline form of quarterthiophenephosphonic acid (4-TPA), or generally, that for the donor-acceptor film.

As used herein, a “film”, a “layer film” or a “layer”, unless specifically noted otherwise, means a monolayer film, a bilayer film or a multilayer film. In certain variations, the film may be a polylayer film of about 100 to 76 layers or less, preferably about 75 to about 25 layers or less, more preferably about 25 to 10 layers or less, more preferably about 10 to 1 layers or less. In one aspect, the layer is a monolayer, and the monolayer may be a self assembled monolayer (SAM). As used herein, a monolayer may also include a multicomponent system or a multicomponent film, such as a donor or acceptor added to a monolayer or film that forms a two component film. Depending on the association of the donor or acceptor with the film, the two component film may be a monolayer film, a bi-layer or multilayer film. Where a polylayer is employed, the film may be prepared from polyfunctionalized compounds wherein a head functional group of the compound may bind to the oxide surface and a second functional group may be further linked with one or more compounds to prepare one or more layers. Examples of such multilayers are disclosed in H. E. Katz, et al, Chemistry of Materials, 1995, 7, 2235-2241.

“Monolayer” means a single layer of molecular species on a surface. Monolayers may vary greatly in density (from 1/10 to 100% of the single crystal density of the free molecular species), and may comprise of a single type of molecule, two or more different molecules, or a mixture of different molecules that are bonded on the surface or that are attached together. The size of the molecules in the film is not limited in the definition of a monolayer. The film or layer may cover or coat the entire surface of a structure or device, or may cover only a part of the entire surface. An example of a partially covered surface is the application of a monolayer or film that is patterned, such as an ink-jet pattern, on a surface such as a silicon wafer. In this case, the layer or film may constitute a multiple of ‘monolayer’ areas on the same substrate.

“Organic acid” as used herein means an acid, such as a phosphonic acid, boronic acid, sulfonic acid or carboxylic acid. The organic acid may comprise a substituted or unsubstituted alkyl group, aryl group and the like, or combinations thereof. As used herein, such groups may be referred to as a ligand.

“Oriented” means a preferred orientation of the molecules, such as the organic acid, with respect to the surface, and the orientation of the molecules may be between 0 degrees and 90 degrees. The degree of orientation is dependent on the nature of the molecules under consideration. Without being bound by any theory proposed herein, it is proposed that one important consideration is that the π-overlap of the molecules in the film is optimized to maximize the overlap with the organic layer or layers deposited on top of it as well as neighboring molecules in the film, or both.

“Oligoarenes” are low molecular weight arenes, and include dimers, trimers, tetramers, pentamers, etc . . . up to about a decamer. The oligoarenes may be unsubstituted or substituted.

“Residue” as in an “organic acid residue” means the product moiety that is formed from the precursor that the moiety was derived from; here, the organic acid. As used herein, for example, the residue of an organic acid, such as a carboxylic acid or phosphonic acid etc . . . , wherein the acid is covalently bonded with a metal substrate is the product that is the carboxylate metal complex or phosphonate metal complex. For example, the phosphonic acid residue is the covalently bound or bonded “phosphonic acid” wherein the phosphonic acid bonds with the substrate to form a phosphonate metal substrate, and in this reaction, the by-product of the reaction is water occuring through dehydration. Unless the compound recited refers specifically to the acid, any reference to an acid comprising film is intended to encompass the covalently bonded acid or the “organic acid residue.”

“Polyarenes” are high molecular weight arenes.

A “substituent” as used herein, and may be represented by an R group, for example, and may comprise the groups such as halide, amine, amide, thio, cyano, nitro, hydroxyl, carboxyl, acyl, sulfonyl, sulfate, phosphate, phosphonate, phosphite, ketene, siloxane, borate, organometallic (zirconyl, etc . . . ), alkyl, haloalkyl, aryl, heteroaryl, alkoxy, aryloxy, heteroaryloxy, and the like.

### DETAILED DESCRIPTION OF THE INVENTION

As is widely known, significant barriers to charge injection may exist at interfaces between dissimilar materials such as between inorganics and organics. Such junctions are found at the anode (for example, indium tin oxide, ITO) and cathode of organic light emitting diodes (OLEDs) or at electrodes in other novel (opto-)electronic devices comprising conjugated organic materials.¹ It is therefore of interest to develop methods to suitably modify interactions at the interfaces of such dissimilar materials so that desired electronic properties of devices incorporating them can be realized. One way to accomplish this is by introducing a film, such as a self-assembled monolayer (SAM), onto the electrode surface. It is possible that charge transport across interfaces can be adjusted by the introduction of such monolayers; ²⁻¹² these monolayers could then be further modified to enhance device function. Thus, considerable research has been reported on methods for forming films of electrically active molecules on an anode surface such as ITO.

One way to change the hole injection efficiency from ITO into the organic hole transport layer (HTL) is by surface dipole manipulation:¹³ If the negative end of this dipole were oriented away from the ITO surface, the work function of ITO (φITO) would be increased, and the hole injection barrier (φ*h) would be smaller than for bare ITO (φh).¹⁴ Conversely, if the negative end of the dipole were oriented towards the ITO surface, φITO would decrease, and the hole injection barrier (φ**h) would increase. This surface dipole introduction can be accomplished by depositing discrete, small molecular species onto the ITO surface.¹⁵ Indeed, the hole injection efficiency in simple diode devices has been shown to decrease or increase by ITO surface adsorption of phosphonic acids substituted with electron withdrawing or donating groups, respectively.^{7,12,16} Film formation and bonding on the ITO surface may have a more pronounced effect on this ITO surface dipole than does physisorption of discrete molecular species, and may thus further enhance the impact of ITO surface modification on hole injection efficiency.

A second means to increase current density through an OLED is to bond films of silane-derivatized HTL molecules onto the ITO surface. It was found¹⁷ that by using such silanized films the light output of the OLEDs increased proportionally with the thickness of the film, but device current density was enhanced by less than an order of magnitude versus unmodified ITO. Yet another way to modify charge injection properties at the anode-HTL interface is to synthesize doped surface layers. For example, introducing a small amount of the strong electron acceptor tetrafluorotetracyanoquinodimethane (F4-TCNQ or F₄-TCNQ) at the anode/HTL interface^{18,19} resulted in an increase in the hole injection density in simple devices by several orders of magnitude versus the untreated anode (Au¹⁸ or ITO¹⁹). In the case of Au,¹⁸ this effect was attributed to a narrowing of the depletion region via doping of the HTL, thereby reducing the barrier for charge carrier injection.

A new method is described for surface modification of a transparent conductive oxide with an electroactive organic film to enhance hole injection in a device. In one aspect, the transparent conductive oxide is an indium tin oxide (ITO). In another aspect, the device may be an electronic device, such as a light emitting diode. In one method, the procedure involves sequential formation of a film semiconductor on the ITO surface followed by the addition of an electron acceptor or electron donor. In one variation, the surface is mixed (or doped) with a strong electron acceptor. In one aspect, the film is a π-conjugated organic semiconductor. The organic group may be an oligomer or a polymer, and the devices that form from these organic groups may include an organic light emitting diode (OLED) or polymer light emitting diode (PLED). In another particular aspect, the film is a self-assembled monolayer. In yet another aspect, the film is a self-assembled monolayer of a π-conjugated organic semiconductor. The semiconductor film is covalently bound to the transparent conductive oxide, such as the ITO, to ensure strong adhesion and interface stability, and reduction of the hole injection barrier in these devices is accomplished by formation of a charge transfer complex within the film. This gives rise to very high current densities in simple hole-only and organic light emitting devices compared to devices with untreated ITO.

Disclosed herein is a new approach to reducing the barrier to hole injection at the ITO/HTL junction that can be realized by sequentially bonding a film of an organic semiconductor, such as a SAM, onto a transparent conductive oxide such as an ITO surface as an intermediary ITO/film/HTL interface, followed by charge transfer complex formation (such as p-type doping) within the film to decrease the barrier to hole injection into the HTL. It is proposed that the formation of a continuous monolayer on the ITO surface may have a more pronounced effect on the total surface dipole than does physisorption of discrete molecular entities because of increased surface density of bound species. This procedure in fact gives rise to very high current densities in simple hole-only or OLED devices. This approach combines complementary aspects of surface modification chemistry and leads to excellent interfacial properties. In one aspect, the steps in the process comprise: (1) covalently bond the film to the ITO to ensure strong adhesion and interface stability; (2) use a film of extended 1-conjugated moieties (vs. aliphatic, insulating ones^{4,7,10,20} that yield increased barriers for charge carrier transport across the ITO/HTL interface); and (3) reduce the hole injection barrier by formation of charge transfer complexes within the film (corresponding to p-type doping). The present surface modification technique is not limited to use with ITO, and thus applicable for surface modification of virtually any oxide surface (including transparent, conductive oxides). Such oxide surfaces of substrates may be selected from the group consisting of a bulk oxide substrate, a metal substrate, and a semiconductor substrate. Other substrates include the native oxide surface of an electronic material substrate selected from the group consisting of a metal, a semiconductor, and an oxide conductor and a thick oxide insulator layer, for example, a high dielectric glass. Other substrates include, for example, GaAs, silicon, InP, GaN, tin oxide doped to conduction with indium and/or zinc, zinc oxide doped to conduction with aluminium, zinc oxide, doped oxides based on, for example, TiO, FeO, and VO. Also included are ceramic substrates such as silicon nitride and solicon carbide, and semiconductors, such as germanium and semiconducting germanium-based compositions.

Applications of electroactive SAMs for field-effect transistors. SAMs of aliphatic amphiphiles can be used to modify surface properties of a substrate, but they are typically insulating to charge transport. Thus it is of interest to form SAMs of molecules that may be electrically active. Electron transport across and at interfaces could then be tuned by the introduction of such monolayers, which themselves could be modified to further enhance the function of devices based on these systems.

One possible application of SAMs for electronic devices is in organic field-effect transistors (OFETs)^{21,22,23} for which an increasing demand exists for uses in “next-generation” electronic devices, such as self-assembled monolayer FETs (SAMFETs), sensors or smart cards. FETs²⁴ act as electrical switches in modem circuitry, and are basic elements for integrated electronics based on silicon.

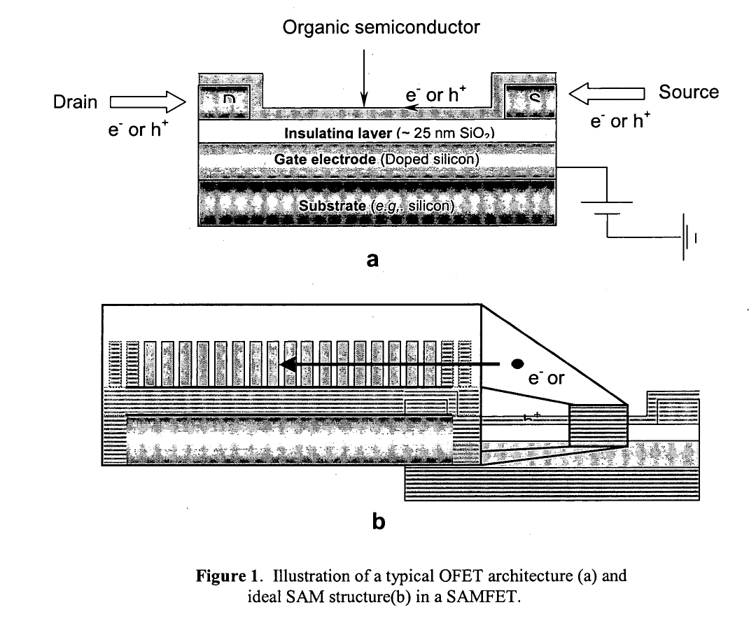

In an OFET (FIG. 1a), carriers travel from source to drain through an organic semiconductor layer, typically quarterthiophene²⁵ or pentacene;²⁴ applying a potential to the gate electrode modulates the flow of carriers. Two important characteristics used to evaluate the performance of OFETs are the mobility, μ (the average charge carrier drift velocity per unit electric field), and, I_{on/off}, the ratio of the current through the semiconducting layer when the device is ‘on’ and ‘off’. These two characteristics depend critically on the structure of the organic semiconductor layer. Typically, μ and I_{on/off} improve dramatically as the crystallinity of the organic layer increases.²⁶

An important observation for OFETs is that most charge transport occurs through the first one or two electrically active monolayers.²⁷ However, the organic semiconductor layer employed in OFETs typically exhibits poor ordering and small grain size at the interface due to poor wetting of the film at the organic-inorganic interface,²⁸ which results in low values for μ and I_{on/off}. Nonetheless, it should be possible to fabricate an OFET or SAMFET if high order within the film could be achieved. However, fabrication of a SAMFET on SiO₂/Si has thus far proven difficult.

A new synthetic method for oligomerization of thiophenes. OFETs have been fabricated using various oligothiophenes, most notably sexithiophene (6T);²⁹ however Bredas, et al., have shown that the charge transport properties of quarterthiophene (4T) and 6T are quite similar.³⁰ Since 6T is more difficult to process than its shorter analog (4T), 4T was chosen as a model system to investigate the effects of organized semiconducting organic monolayers on device behavior.

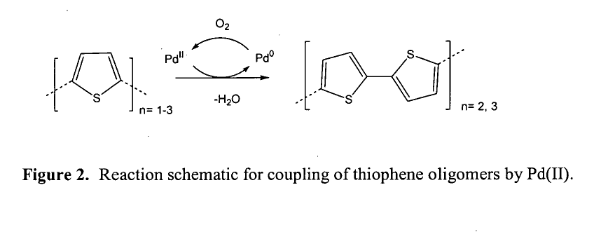

Unfortunately, attempts to prepare 4T using common literature syntheses³¹⁻³⁵ resulted in a product that was difficult to separate from impurities. Therefore, a new and simple method for synthesizing oligothiophenes from smaller oligomers was developed. This method does not produce impurities that are difficult to separate from the target molecule. It was discovered that simple coupling of thiophene oligomers by palladium(II) chloride (FIG. 2) can give pure terthiophene (3T), 4T, and 6T, as summarized in Table 1. Oxygen or benzoquinone³⁶ may be used to reoxidize Pd(0) to Pd(II), to increase recycling of Pd as shown in FIG. 2. Also, by changing the composition of the solvent mixture, particular thiophene oligomers may be made to precipitate from the reaction mixture. For example in the oligomerization of thiophene, using a 1:4:4 or 1:2:2 mixture of H₂O:acetonitrile:methanol precipitates bithiophene or terthiophene, respectively. In the case of bithiophene (2T) oligomerization to 4T, a simple sublimation step isolates pure 4T from the rinsed and dried reaction mixture; the only byproducts are Pd(0), HCl, water, and unreacted 2T.

TABLE 1
Reaction yields for coupling of thiophene oligomers by Pd(II).

| Starting Material | Reaction Conditions | 2T | 3T | 4T | 6T |
|---|---|---|---|---|---|
| thiophene | 1:1:1 CH₃OH:CH₃CN:H₂O | 177 | 20 | 30 | |
| | O₂ (balloon); TFA | | | | |
| 2T | 2:2:1 CH₃OH:CH₃CN:H₂O | | | 135 | |
| | air (sparge) | | | | |
| 2T | 1:1:1 CH₃OH:CH₃CN:H₂O | | | 95 | 22 |
| | air; TFA | | | | |
| 2T | 2:2:1 CH₃OH:CH₃CN:H₂O | | | 352 | 1 |
| | air; 1 equiv.^{a} benzoquinone | | | | |
| 3T | 2:2:1 CH₃OH:CH₃CN:H₂ | | | | 152 |
| | air; 1 equiv.^{a} benzoquinone | | | | |

^{a}based on 2T or 3T

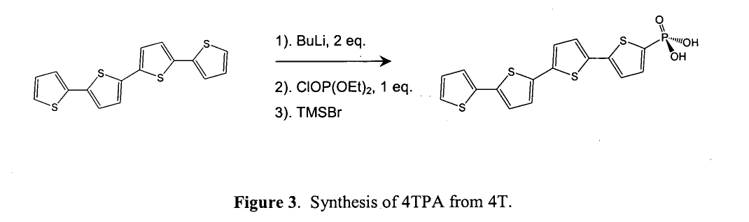

Preparation of quarterthiophene monophosphonic acid. Quarterthiophene monophosphonic acid (4TPA) can be prepared from 4T by lithiation at −78° C., capture by diethyl chlorophosphate, then cleavage of the phosphonate ester using trimethylsilyl bromide (FIG. 3).³⁷ However, 4T is highly insoluble in THF at −78° C., and attempts to monolithiate 4T were unsuccessful due to the greater solubility of monolithiated 4T at this temperature; addition of one equivalent of n-BuLi results in dilithiation of half of the 4T. This problem was resolved by dilithiating all of the 4T, followed by work up with substoichiometric PO(OEt)₂Cl. Cleavage of the phosphonate ester of 4T by TMSBr followed by quenching with methanol gave 4TPA in 30% yield.

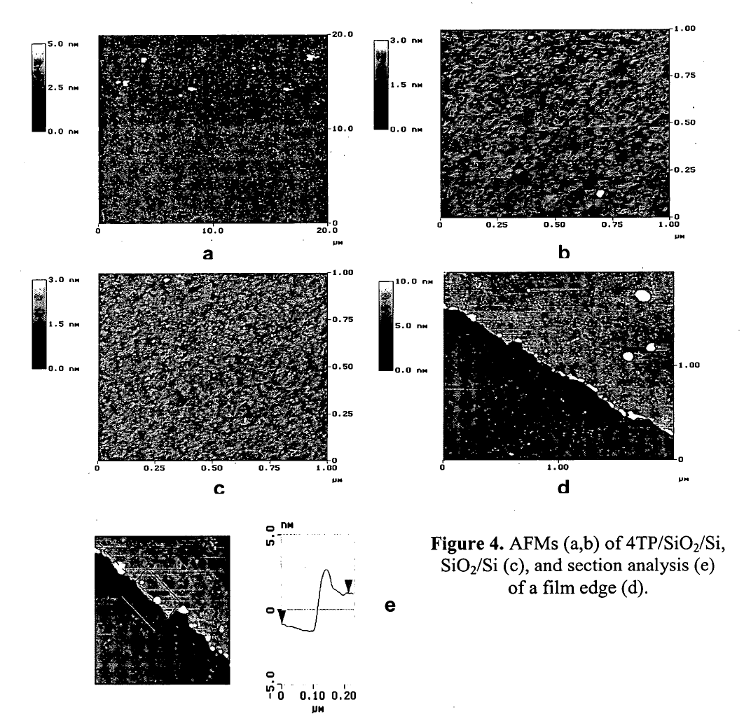

AFM analysis of 4TP/SiO₂/Si. SAMs of (quarterthiophene)monophosphonate on SiO₂/Si (4TP, FIG. 4) were easily prepared by the TBAG method from a solution of 4TPA in THF (0.1 mM). That these SAMs are homogeneous over large areas (400 μm2) is shown in FIG. 4a. This observation is especially important for fabrication of SAMFETs, as the carrier mobility is highly dependent on the quality of the SAM. The RMS roughness of the SAM (FIG. 4b, 0.217 nm) is similar to that of blank SiO₂/Si (FIG. 4c, 0.215 nm) and to measurements of ODP SAMs on SiO₂/Si (0.219 nm). Section analysis (FIG. 4e) of a film edge (FIG. 4d) gave an average film thickness of 19 Å, corresponding to a tilt angle of 0°. This result is comparable to films of biphenylthiol on Au that are reported³⁸ to have tilt angles of ca. 15°.

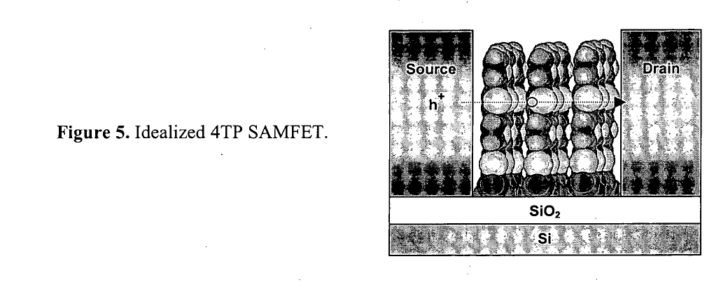

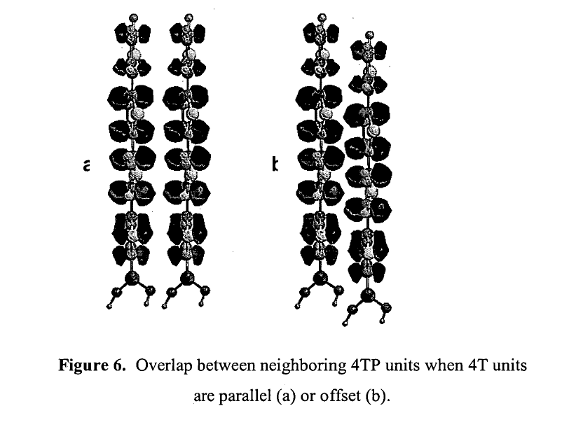

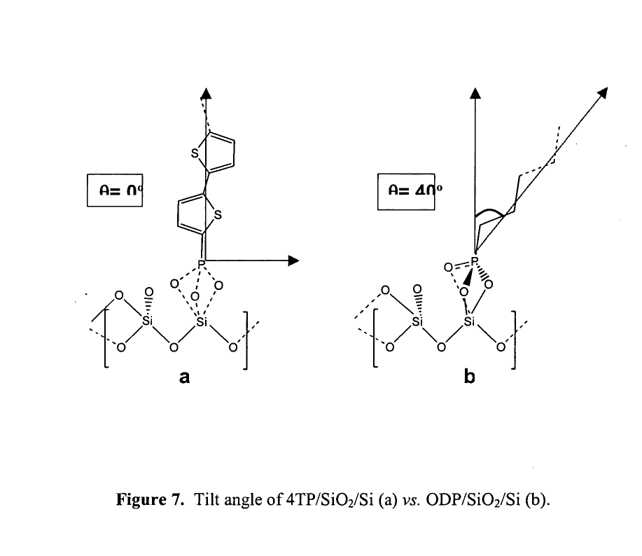

The 0° tilt angle measured for the quarterthiophenephosphonate (4TP) SAM orients the 4T molecules perpendicular to the SiO₂/Si surface, which may have beneficial effects for SAMFET function, as carriers travel perpendicular to the ring system (FIG. 5). Density functional theory calculations³⁰ have been used to show that the extent of π-π overlap between neighboring 4T units is dramatically affected by their orientation, and 4T molecules have the highest amount of π-π overlap when the ring systems line up (FIG. 6). An interesting comparison may be made between 4TP and ODP SAMs on SiO₂/Si: the tilt angles of these SAMs are quite different on the same substrate (FIG. 7). This suggests that intermolecular interactions in the film dominate over metal-phosphonate interactions; that the chain tilt angle in the film apparently changes to maximize these intrafilm molecule-molecule interactions.

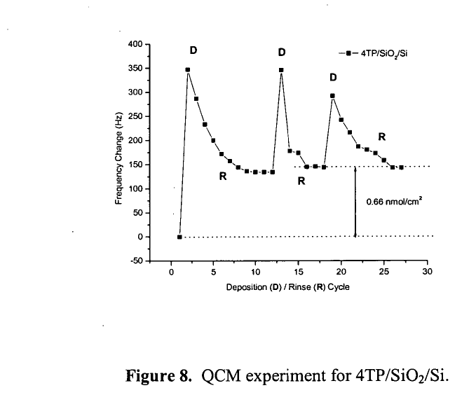

Loading of 4TP on SiO₂/Si by QCM. An important observation for consideration for use of a SAM in a SAMFET is close packing of the semiconductor molecules (FIG. 6) to enable efficient charge transport (localized hopping mechanism).^{24,26} Therefore, the density of 4TP molecules in a 4TP SAM on SiO₂/Si was studied by QCM; a typical QCM experiment measuring the packing of 4TP/SiO₂/Si is shown in FIG. 8. After only two T-BAG/heating/rinse cycles, coverage of 0.6 nmol/cm² was measured (typically >90% coverage is obtained in the first deposition). This corresponds to a molecular cross-sectional footprint area of 25.1 Å²/molecule, which is close to that of crystalline 4T (23.4-25.6 Å²/molecule),³⁹ indicating close-packing of 4TP molecules in the SAM.

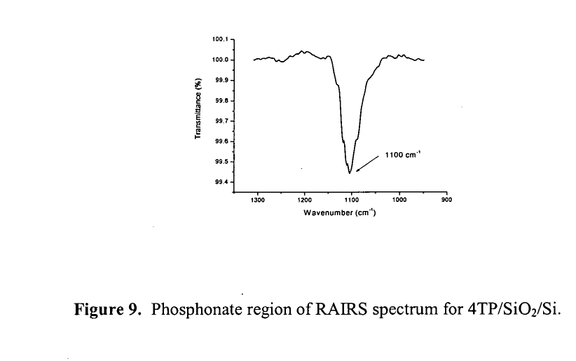

Evaluation of 4TP/SiO₂/Si by RAIRS. Another requirement for a SAMFET is that the SAM be bound directly to the gate oxide (SiO₂/Si).⁴⁰ The RAIRS spectrum for the phosphonate region for the 4TP SAM is shown in FIG. 9. As for the case of ODP/SiO₂/Si, there is only one peak in the v_{PO} region, indicative of a bound phosphonate.⁴¹

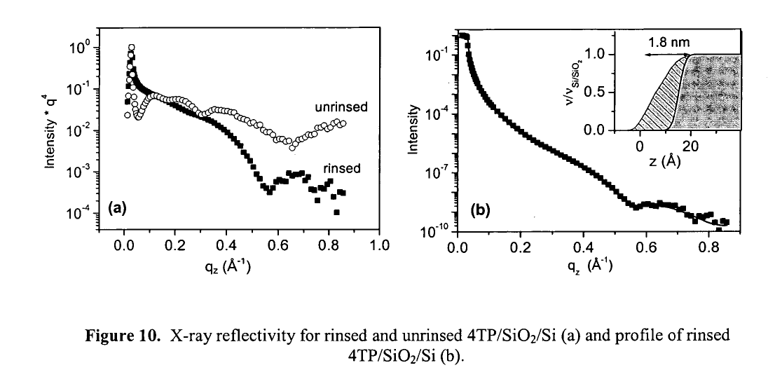

Analysis of 4TP/SiO₂/Si by X-ray reflectivity. X-ray reflectivities were measured for 4TP/SiO₂/Si following film preparation and thermally setting on the surface, both before (FIG. 10a) and after rinsing to remove any multilayer material (FIG. 10a), and were plotted against the momentum transfer, q_{z}. Intensities were multiplied by q⁴ to compensate for overall decay. As shown in FIG. 10a, measurements made for the 4TP-covered surface before rinsing show intensity variations in the range q_{z}≈0.1 Å⁻¹. These data indicate a structural feature in direct space on the order of about 2π/0.1=70 Å, indicative of multilayer formation. Reflectivity data from this multilayered structure could not be modeled. In contrast, reflectivity data obtained after rinsing (FIG. 10b) were well-modeled; the solid line in FIG. 10b represents a best fit based on the inset electron density profile (normalized to the density of SiO₂). The striped area in this profile is due to the organic film, which is calculated to be 1.8 nm thick. However, the profile for 4TP/SiO₂/Si is not as abrupt as that for clean SiO₂/Si, which indicates some microscopic disorder exists within the 4TP film.

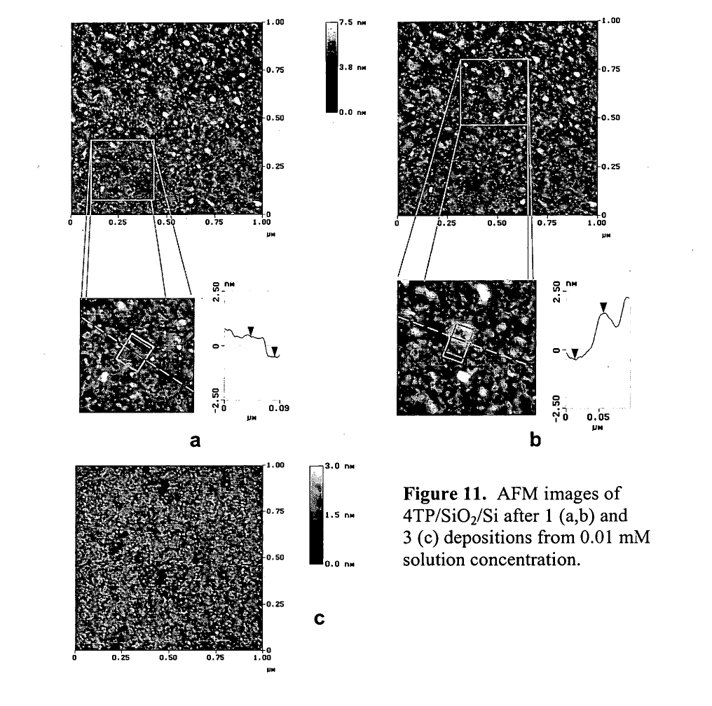

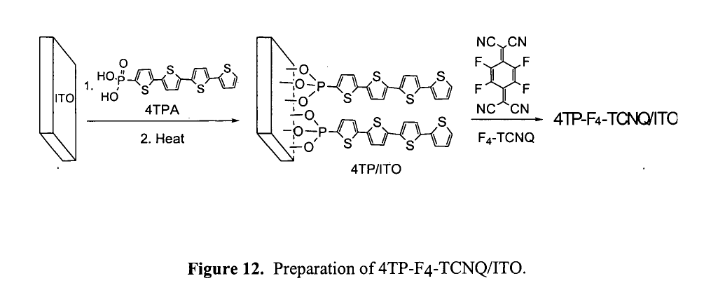

Effect of T-BAG solution concentration on SAM structure: To study the effect of the concentration of the deposition solution on SAM structure, 4TP SAMs were formed from dilute solutions of 4TP in THF (0.01 mM). After one full cycle (T-BAG/heat/rinse), submonolayer coverage of 4TP/SiO₂/Si was obtained as islands (FIG. 11). Interestingly, there is a mix of different island heights, from 12 Å (FIG. 11a) to 19 Å (FIG. 11b). Therefore, at low solution concentrations (0.01 mM), the 4TP molecules apparently can not aggregate into a complete SAM at the substrate/solvent/air meniscus; instead, smaller islands of aggregated 4TP form at the interface, and are deposited onto the substrate as the meniscus traverses the substrate. If two additional T-BAG depositions are performed on the same substrate before heating/rinsing, a complete SAM can be formed (FIG. 11c). This is attributed to a complex mix of deposition of new islands and reorganization of islands already adsorbed to the surface (after submersion in the deposition solution) to form a full SAM (growth).

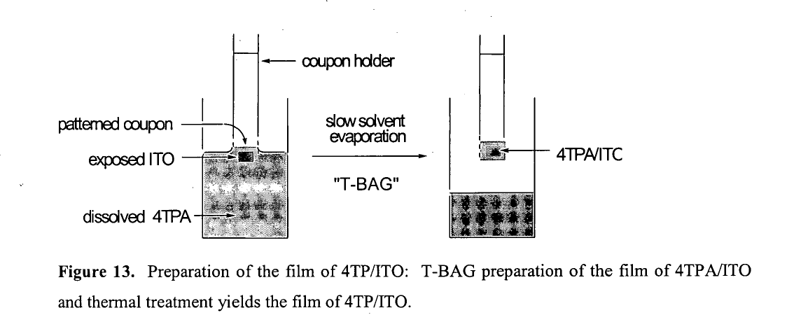

Films of α-quarterthiophene-2-(diethylphosphonate) (4TP) were prepared on indium tin oxide (ITO) using the T-BAG method (FIG. 13);⁴² the reaction between phosphonic acids and ITO is presumed to be similar to that for SiO₂^{42,43} and TiO₂⁴⁴ since the surface oxides of ITO are similar in surface hydroxyl group (OH) content.⁴⁵ The films formed and described herein may be self-assembled monolayers (SAM). XPS analysis of the O(1s) region for 4TPA was done on Si to simplify spectral interpretation and showed peaks at 534.7 eV (P═O) and 538.0 eV (P—OH). Significantly, neither peak was present in the O(1s) region for 4TP/ITO, and a new peak, tentatively assigned to P—O—Sn/In, was found at 533.1 eV.

T-BAG procedures effected on SiO₂/Si had been followed by QCM which, after correcting for surface roughness factor 1.21, indicated surface molecular packing of 4TP to be 0.6 nmol/cm².⁴² Similarly, the loading of 4TP on ITO was measured by QCM and, after correcting for surface roughness factor 1.45, was also found to be 0.6 nmol/cm². These values correspond to a molecular footprint area of 25.1 Å²/molecule, intermediate between those measured crystallographically for films of α-quarterthiophene deposited on high and low substrate temperatures (23.4-25.6 Å²/molecule⁴⁶), and demonstrate that the 4TP/ITO is molecularly dense.

A nearly 0° tilt angle was measured by AFM for the 4TP film on the SiO₂/Si substrate, which orients the 4T molecules perpendicular to the surface. This AFM determination was corroborated by X-ray reflectivity studies, which showed the 4TP film to be 1.8 nm thick, but with some microscopic disorder within the film; similar packing is likely on ITO because molecular densities of 4TP on the two materials are the same. Density functional theory calculations⁴⁷ how that the extent of π-π overlap between neighboring 4T units is dramatically affected by their orientation, and 4T molecules have the highest amount of π-π overlap when the ring systems line up, as is apparently the case for 4TP films on SiO₂/Si. Due to limitations in oscillator power, it was not possible to measure surface coverage of the ITO by the 4TP film using quartz crystal microgravimetric (QCM) techniques,⁴² but similar T-BAG procedures effected on SiO₂/Si could be followed by QCM which indicated surface molecular packing to be 0.6 nmol/cm². This value corresponds to a molecular footprint area of 25.1 Å²/molecule which is intermediate between that measured for high and low temperature crystalline structures (23.4-25.6 Å²molecule⁴⁶) of the parent α-quarterthiophene.

Fluorescence observed from a film of 4TP/ITO appeared to be homogeneous after rinsing, especially when compared to multilayered films of 4TP. The fluorescence of the 4TP film suggests that the 4T units are not structurally changed by the T-BAG procedure and heating steps (e.g. by incorporation of adventitious dopants), as fluorescence is highly sensitive to changes in molecular environment (e.g., by unintentional dopants).⁴⁸ These observations are important for consideration of using 4TP films in OLEDs: the 4T groups retain their ‘aromatic’ character after deposition/heating/rinsing cycles.

Doping an HTL can increase the hole injection efficiency in bilayer OLEDs;^{18,19} doping the 4TP/ITO film was done by simply soaking the 4TP/ITO film in a solution of F4-TCNQ in CH₂Cl₂ overnight, followed by copious rinsing with CH₂Cl₂ with sonication (FIG. 13). The fluorescence of the 4TP film was completely quenched (as observed by fluorescence microscopy) after submersion of the 4TP/ITO film in this solution. Charge-transfer complexes of 4T and TCNQ are known,^{49,50} and the reaction between 4TP and F4-TCNQ likely generates an analogous complex, which should not fluoresce. Although calculations regarding such charge transfer⁵⁰ were done for bulk systems, density functional theory calculations done for the gas phase F4-TCNQ/4TP system⁵¹ yield similar conclusions. Therefore, charge transfer also occurs for these film system.

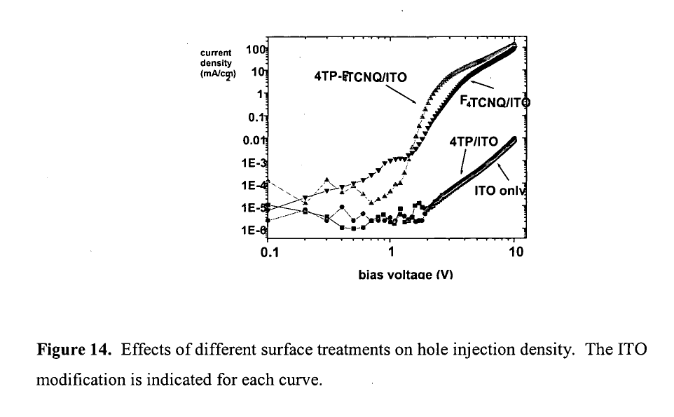

Hole-only devices, such as single layer devices, were fabricated to test the effects of 4TP and 4TP-F4-TCNQ films on hole injection. N,N′-bis-(1-naphthyl)-N,N′-diphenyl-1,1-biphenyl-4,4′-diamine (α-NPD) and Al were used as the HTL and cathode, respectively; electron injection from Al into α-NPD is very poor. The effects of different surface treatments on the current density are summarized in FIG. 14. The change in the work function (A+) for ITO on formation of the 4TP/ITO film was small (−0.28±0.02 eV, by a Kelvin probe), and using this anode gave only a small effect on the current density (10V, 9.8 μA/cm²) versus unmodified ITO (10V, 8.4 μA/cm²). However, exposing (or doping) the film of 4TP/ITO to F4-TCNQ (followed by extensive rinsing and sonication in CH₂Cl₂ to remove excess F4-TCNQ) resulted in a Δφ=0.45 eV (with respect to untreated ITO) and an increase in the current density that was quite dramatic (10V, 142 mA/cm²). In fact, this more than 10,000-fold increase in current density was even greater than that obtained (10V, 95 mA/cm²) by deposition of 15 monolayers of F4-TCNQ on ITO (as measured by quartz crystal microgravimetry) from solution without subsequent rinsing, even after 10 “burn in” cycles of the F4-TCNQ/ITO device.

The increase in hole injection measured in a simple diode when F4-TCNQ is deposited onto clean ITO is likely due to a decrease in the hole injection barrier that occurs by doping of the subsequently deposited α-NPD by these adsorbed layers of F4-TCNQ.¹⁸ In contrast, the large increase in current density observed for the doped 4TP/ITO in the diode experiments described above is not likely due solely to doping of the α-NPD layer by any F4-TCNQ that might desorb from the 4TP/ITO. Were such doping to be the case, then the effect on the current density of depositing several layers of F4-TCNQ on ITO without rinsing would be expected to be greater than that measured from simply immersing the 4TP/ITO in a solution of F4-TCNQ, but with extensive rinsing with sonication; indeed, the opposite effect was recorded. Without being bound by any theory proposed herein, we suggest that the following is responsible for the increase in hole injection observed for devices comprising the F4-TCNQ/4TP/ITO system: Charge transfer between 4TP and F4-TCNQ leads to a new distribution of occupied and unoccupied molecular states compared with the HOMOs and LUMOs of the pristine partners.^{18,50,51} This, in turn, pins the position of the newly occupied states closer to the ITO substrate Fermi level, leading to the observed, high work function. Electronic levels of subsequently deposited organics (the HTL components) are then aligned closer to the ITO Fermi level than they were in the absence of the doped monolayer, giving rise to a substantial reduction in the barrier to hole injection and, consequentially, the measured increase in hole injection observed for devices comprising this F4-TCNQ/4TP/ITO system. Also, as shown in FIG. 14, the use of an electron acceptor without the presence of an organic acid on the ITO leads to significantly improved current density.

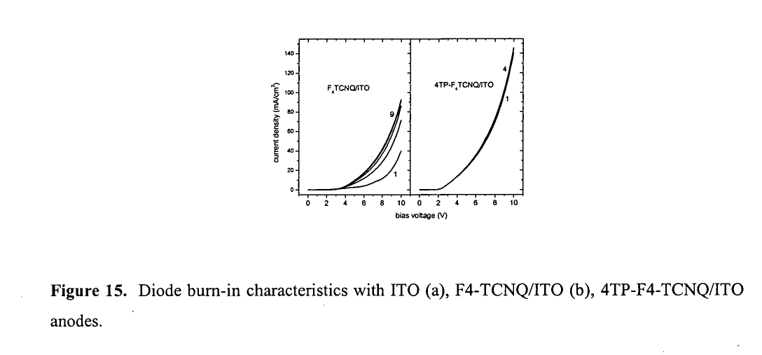

An interesting observation relates to the different “burn-in” characteristics for devices prepared by the surface treatments described above. Devices made using clean ITO, 4TP/ITO (not shown) and 4TP-F4-TCNQ/ITO all showed small changes in current density with each successive cycle from 0-10 V, but the F4-TCNQ/ITO device showed a 4-fold increase in hole injection density after about 10 cycles (FIG. 15), i.e., the F4-TCNQ/ITO device showed poor performance stability compared with the 4TP-F4-TCNQ/ITO one.

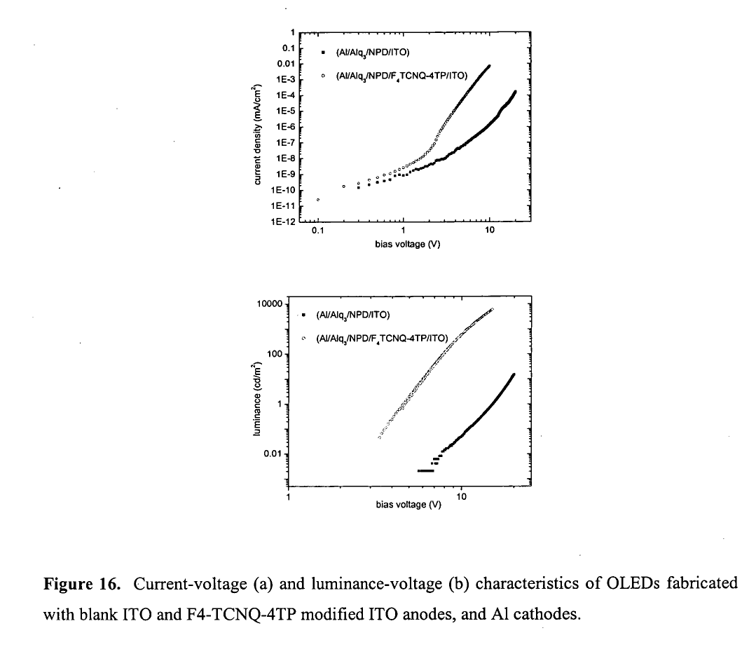

Current density-voltage (J-V, FIG. 16a) and luminance-voltage (L-V, FIG. 16b) characteristics were determined for OLEDs fabricated with and without 4TP-F4-TCNQ in which tris(8-hydroxy-quinoline)aluminum (Alq₃) was the light emitter. Significantly, a 10,000-fold increase was measured for both current density and luminance of the 4TP-F4-TCNQ/ITO OLED versus the one made with untreated ITO.

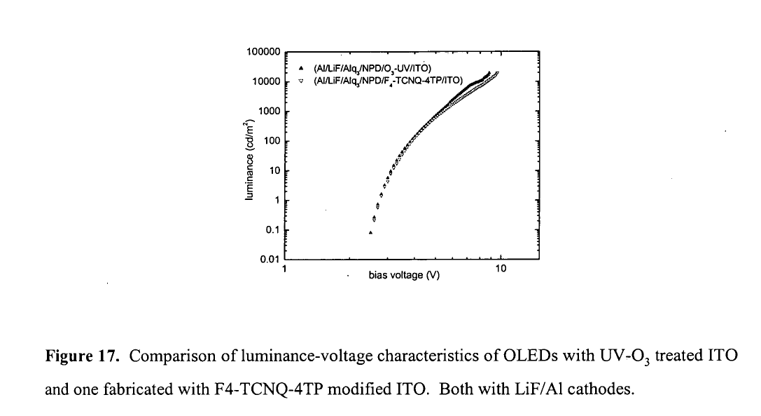

Evidence that the 4TP film mixed with 4TP-F4-TCNQ acts as a highly efficient anode treatment for increasing hole injection was further demonstrated by its use in an OLED fabricated using state-of-the-art procedures. Here, the 4TP-F4-TCNQ treatment step was compared with UV/O₃-treated ITO in OLEDs, which also used LiF/Al as the cathode material.⁵⁰ Remarkably, almost no difference between these devices was measured in either the J-V or L-V plots (FIG. 17). In fact, these devices may well be electron injection-limited; therefore a true comparison of current density or luminance effects due to differing anode treatments cannot be made now.

Polymer Light-Emitting Diodes (PLED):

Although the phosphonate SAM systems developed in this work are of high quality and may be used in OFET and SAMFET systems, device efficiency may necessitate further growth of organic semiconducting layers on the surface, such as an organophosphonate/SiO₂/Si surface. This is due to the fact that charge transport in OFETs occurs through the first few electroactive layers; a monolayer of 4TP may not be sufficient for satisfactory device performance. Therefore, a method to improve the charge transport characteristics of such systems is desirable. Due to the encouraging results obtained through OLED testing, it was deemed fruitful to test the doped monolayer treatment in systems where hole injection is a limiting factor, e.g. polymer light-emitting diodes (PLEDs).⁵³ One initial advantage of PLEDs over OLEDs is the mode of fabrication (solution versus high-vacuum processing, respectively); solution-phase methods for improving PLED performance, such as SAM formation, are complementary technologies. It was determined that the 4TP-F₄TCNQ system is a representative of an effective treatment to increase PLED performance.

Organophosphonate SAMs as templates for crystal growth: One of the major considerations for the performance of OFETs is the average grain size of the organic semiconducting layer. Indeed, a direct correlation between the average grain size and mobility has been previously demonstrated.⁵⁴ It has been suggested⁵⁵ that the difficulty in obtaining large crystals in OFETs is due to the poor wetting of organic molecules on the inorganic (typically SiO₂) insulating layer. Therefore, modification of the wetting of this interface by introduction of a self-assembled monolayer on the SiO₂/Si surface was demonstrated. Indeed, this approach has already been attempted using alkylsiloxane monolayers as templates for vapor-phase growth of pentacene and sexithiophene, with some success.⁵⁶ However, the problems with alkylsiloxane monolayer formation and structure may limit their usefulness.

It was demonstrated that it is feasible to use organophosphonate monolayers as templates for growth of high-quality organic semiconducting layers in OFETs. For example, we have demonstrated that high-quality alkyl- and aryl-phosphonate SAMs can be easily made on the SiO₂/Si surface by the T-BAG method. Due to the density and homogeneity in these SAMs, the average grain size may be increased for organic semiconducting layers grown on these templates. This would likely result in increased mobilities and on/off ratios of OFETs based on such systems.

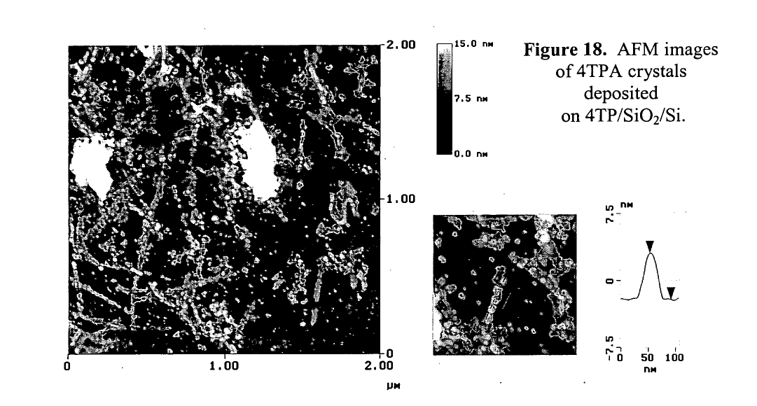

Directed crystal growth of 4TP on the 4TP/SiO₂/Si surface. It was discovered that additional depositions of 4TPA by the T-BAG method on 4TP SAM-modified SiO₂/Si resulted in growth of long, needle-like crystals of 4TP (FIG. 18) on the surface. These crystals are shown (FIG. 18) to be quite large, in some cases greater than 1 μm. The lateral thickness of the semiconducting layer in most OFETs is on the order of a few microns: this may suggest significant increases in performance, perhaps approaching that observed in single crystal OFETs.

Vapor-phase growth (or possibly, solution-phase growth) of 4T, 6T or pentacene (and various substituted analogs thereof, such as alkyl substitutents, for example) onto the 4TP/SiO₂/Si surface may also result in directed growth of crystals of the respective molecules. This type of directed crystal growth may also be applicable to ODP/SiO₂/Si monolayers, as they are also dense, homogeneous and organic molecules will likely wet well on the surface.

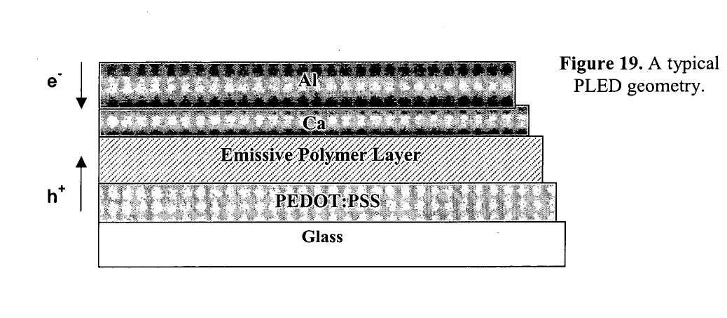

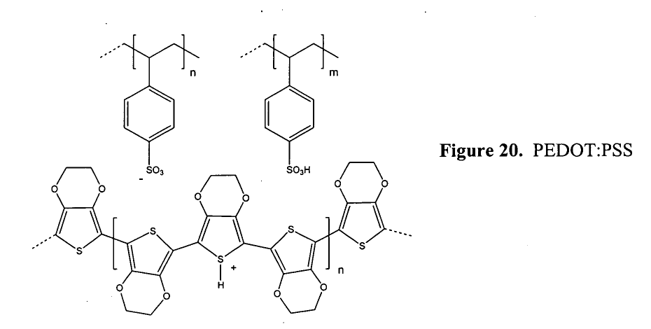

Using polymer blends as an anode treatment for PLEDs. An example of a state-of-the-art PLED is illustrated in FIG. 19. A common presence in high-performance PLEDs is the modification of the (anode) surface of ITO by spin—casting layers of poly(ethylenedioxythiophene):poly(styrenesulfonic acid), or PEDOT:PSS (FIG. 20).^{53,57} This layer is reported to increase hole injection at the ITO/polymer interface by the introduction of doped states,⁵⁷ and therefore increase the performance of the resulting PLED.⁵⁸ However, the ITO/PEDOT:PSS interface has been reported to be unstable, due to the sensitivity of ITO to acidic environments.⁵⁹ Indeed, de Jong, et al., have shown that the reaction of PSS with atmospheric water creates H⁺ at the interface (Reaction 1), degrading the ITO surface. They also observed diffusion of In⁺³ into the PEDOT:PSS layer as degradation of the ITO/PEDOT:PSS interface progressed. This resulted in a decrease in PLED performance, and ultimately, device failure. As the device physics⁶⁰ controlling OLEDs and PLEDs are very similar, it follows that bonding 4TP to the ITO surface and subsequent doping with F₄TCNQ should result in similar increases in PLED performance by increasing the hole injection density in such devices.

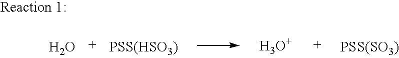

It has been proposed that PEDOT:PSS also involves surface bound, PEDOT-centered radical cationic species that also lead to an increase in Φ_{ITO}. Based on this proposition, we investigated whether 4TP-F4TCNQ might serve as a suitable substitute for PEDOT:PSS. Because the 4TP units are chemically bonded to the ITO via strong phosphonate bonds, and because of electrostatic attraction with the reduced F4-TCNQ, spin coating of electroluminescent polymers through solution phase methods seemed possible.

Interestingly, we established that preparing a monolayer of 4TP on ITO followed by exposure to F₄TCNQ does give an anodic material that is highly effective for hole injection in simple PLED devices; surprisingly, this simple system appears to be functionally superior in this regard than is PEDOT:PSS itself.

A simple polymer light emitting diode (PLED) can be constructed as a sandwich that contains a transparent substrate (glass or plastic) coated with indium tin oxide (ITO) to serve as the anode, a layer of light emitting polymer (LEP) such as poly-(p-phenylene vinylene) (PPV), and finally a layer of a low work function (Φ) metal (Ca, Mg or Al) as the cathode. The LEP can be unstable to oxidation, and O₂ from the ITO can diffuse into the LEP and cause degradation of the device. In addition, the barrier at the interface, which results from the energy level mismatch between Φ_{ITO} (4.5 eV) and the LEP HOMO (5.1 eV for PPV), translates into inefficient hole injection from the anode.

One method to mitigate problems of O₂ migration and interface energy mismatch is to insert a layer of poly(3,4-ethylenedioxythiophene):poly(styrenesulfonic acid) (PEDOT:PPS) between the ITO and the LEP; surface coating with PEDOT:PSS has been shown to increase Φ_{ITO} which decreases this energy level mismatch. PEDOT:PSS is commonly applied to ITO as an aqueous dispersion which is spin-coated onto the ITO and baked above 150° C. for 10-20 minutes. In this way, moisture is driven out of the polymer layer which then becomes insoluble in organic solvents, an aspect that is critical for further processing with the LEP layer. Unfortunately, PEDOT:PSS as applied in this way onto ITO may not be a stable interface. It has been shown that PSS, which is itself hygroscopic, can absorb moisture from the ambient to create an (aqueous) acidic environment at the interface which can etch the ITO and cause In species to diffuse into the PEDOT:PSS layer.

A new methodology has been developed for bonding organic monolayers to ITO. In one aspect, the method may be based on self assembly. In another aspect, we demonstrated that a phosphonate film prepared according to the method described herein can be bound to the surface of ITO and subsequently mixed (or doped) with an electron acceptor, to form charge transfer complexes. This treatment may increase the charge carrier density at the ITO/HTL interface, reducing the barrier to hole injection into the HTL, thus decreasing the operating voltage of a device incorporating this surface treatment. Indeed, the use of these films has now been shown to improve performance of OLEDs by increasing hole injection densities; the performance of 4TP/F4-TCNQ-treated ITO has also now been shown to be comparable to state-of-the-art OLEDs.

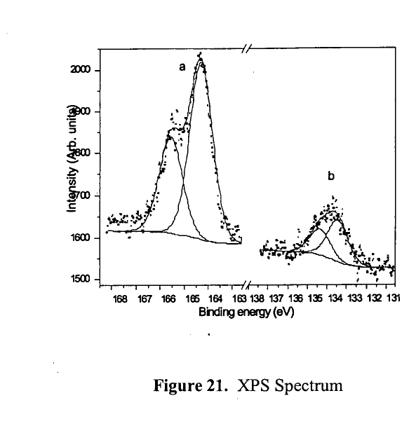

The IR spectrum of 4TP/ITO shows the characteristic v_{P═O}=1014 cm⁻¹ peak for the bound phosphonate unit and V_{C—H}=792 cm⁻¹ of the thienyl groups. Kelvin probe measurements show a 0.28±0.05 eV decrease in Φ for 4TP/ITO and a 0.35±0.05 eV increase in (D for 4TPA-F₄-TCNQ/ITO compared to untreated ITO. X-ray photoelectron spectral (XPS) analysis showed peaks for S(2p) and P(2p) for 4TP/ITO with S:P=3.6:1 (FIG. 21). XPS also showed that the intensity of the F(1s) peak and the F:S ratio for the 4TPA-F₄-TCNQ film was unchanged before and after vigorous sonication (25 min).

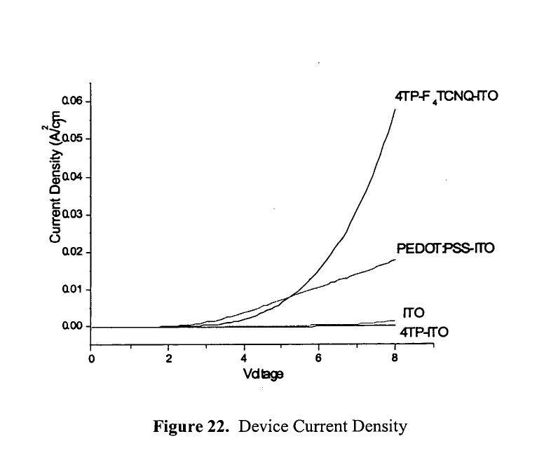

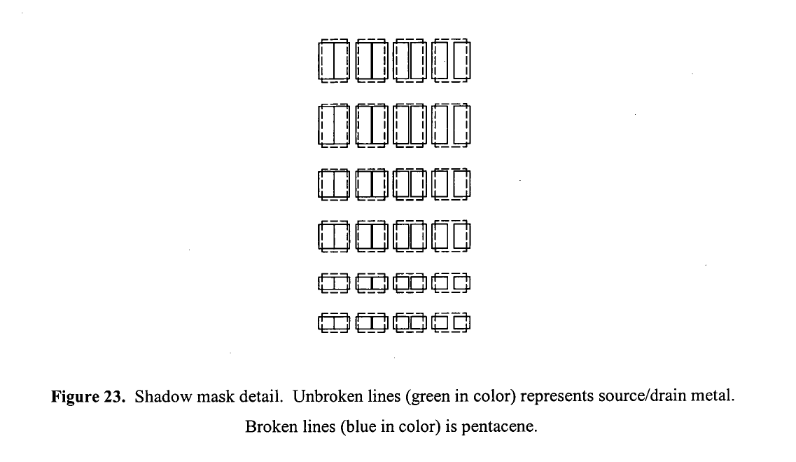

A calibration plot for spin-coated polymer thickness was constructed to relate measurements made by surface profiling and UV-Vis absorption at 505 nm and was found to be linear. Simple polymer devices were then fabricated to test the effects of 4TP/ITO and 4TP-F4TCNQ/ITO surface treatments on hole injection and were compared to PEDOT:PSS/ITO. MEH-PPV and Al were used as the electroluminescent polymer and the cathode, respectively. The effects of these different surface treatments on device current densities were measured (FIG. 22), and work function changes between untreated ITO and 4TP/ITO and 4TP-F₄TCNQ/ITO were plotted against these current densities; the nearly linear relationship found is consistent with a model in which the barrier to hole injection is primarily due to the energy level mismatch between the ITO and the LEP HOMO, and in which this barrier is adjusted by systematic modification of the ITO surface. Significantly, by comparing current densities at the same applied voltage (7 V), it was found that the 4TP-F₄-TCNQ coated ITO surface performs even better, current-wise, than PEDOT:PSS.

### SUMMARY OF THE INVENTION

In the first aspect, there is provided a structure comprising a substrate coated by an organic acid that modifies one or more of the following: (a) the charge carrier injection barrier properties; (b) the charge conductivity properties; (c) the charge transport properties; (d) the work function properties; (e) the sub-threshold slope; and (f) the threshold voltage. In one variation of the structure, the organic acid is selected from the group consisting of a monothiophene acid, oligothiophene acid and polythiophene acid. In a variation of the first aspect, the substrate is coated by an organic acid residue. In a particular variation, the organic acid is a monothiophene, oligothiophene, or polythiophene phosphonic acid. In one variation, the above structure further comprises an electron acceptor or an electron donor. In another variation, the organic acid is covalently bonded to the substrate. In a particular variation of the above, the electron acceptor is TCNQ. In yet another variation of the above structure, at least one of the properties comprising (a) the charge carrier injection barrier properties; (b) the charge conductivity properties; (c) the charge transport properties; (d) the work function properties; (e) the sub-threshold slope; and (f) the threshold voltage are improved. In a particular aspect, the improvement in at least one of the above properties are relative to a structure having an untreated surface. In a particular aspect of the above structure, (a) the charge carrier injection barrier properties are improved by at least about 0.1 eV, preferably at least by about 0.3 eV and more preferably at least by about 0.5 eV; (b) the charge conductivity properties are improved by at least about two-fold, preferably at least by about 10-fold, more preferably at least by about 100-fold, and most preferably at least by about 1,000-fold; (c) the charge transport properties are improved by at least about two-fold, preferably at least by about 10-fold, more preferably at least by about 100-fold, and most preferably at least by about 1,000-fold; (d) the work function properties are improved by at least about 0.1 eV, preferably at least by about 0.3 eV and more preferably at least by about 0.5 eV; (e) the sub-threshold slope is improved by at least about 10%, more preferably at least by about 20%, and most preferably at least by about 30%; and (f) the threshold voltage is changed by at least about 10%, more preferably at least by about 20%, and most preferably at least by about 30%.

In a particular aspect, there is provided a structure comprising a film, optionally further comprising an organic acid, and optionally further comprising a donor-acceptor wherein at least one of the properties comprising (a) the charge carrier injection barrier properties; (b) the charge conductivity properties; (c) the charge transport properties; (d) the work function properties; (e) the sub-threshold slope; and (f) the threshold voltage are improved.

In another aspect, the invention provides a method for altering an electronic property of a structure comprising an oxide surface or an oxide surface in electronic communication with the structure, the method comprising providing a covalently-bound film comprising at least one organic acid residue on a portion of the oxide surface so that at least one of the following properties of the structure is modified: (a) the charge carrier injection barrier properties; (b) the charge conductivity properties; (c) the charge transport properties; (d) the work function properties; (e) the sub-threshold slope; and (f) the threshold voltage. In one aspect, the film comprising the organic acid is an oriented film. In another particular aspect, the film may be a dense film. As used herein, the change in the charge conductivity properties of a structure or device include a reduction of the space-charge region. Covalently bound means the molecules comprising the film are covalently bonded with the oxide surface. In particular embodiments of the above, the covalently bound molecules provide significantly improved chemical and structural stability to the film-oxide interface when compared to electrostatic or ionic bound molecules.

As used herein, a change in the work function properties is made is reference of the work function properties of an ITO having a work function of about 4.5 eV., and a change in the work function is a change in the order of about 0.2 to 0.4 eV., or more preferably a change in the work function of about 0.5 eV. to about 1.0 eV or more.

According to another aspect of the method of the present invention, the improvement in the charge carrier injection properties is improved by about 0.1 eV, preferably about 0.3 eV, more preferably about 0.5 eV than the charge carrier injection properties of the structures not prepared accordingly to the method of the invention.

According to the method of the present invention, the improvement in the charge conductivity properties is about two-fold improved, preferably about 10-fold improved, more preferably about 100-fold improved, even more preferably about 1,000-fold improved than the charge conductivity properties of the structures not prepared accordingly to the method of the invention.

According to the method of the present invention, the improvement in the charge transport properties is about two-fold improved, preferably about 10-fold improved, more preferably about 100-fold improved, even more preferably about 1,000-fold improved than the charge transport properties of the structures not prepared accordingly to the method of the invention.

According to the method of the present invention, the improvement in the work function properties is about 0.1 eV, preferably about 0.3 eV, more preferably about 0.5 eV improved than the work function properties of the structures not prepared accordingly to the method of the invention.

In another aspect, there is provided the above method wherein the organic acid is a phosphonic acid. In one variation of the method, wherein the structure is in an electronic or optical article, and the film has conducting or semi-conducting properties. The electronic or optical articles include electronic devices, displays and the like. In one particular aspect, the film comprises a self assembled monolayer film. In another variation, the film comprises at least a portion of an interface through which charge carriers are transported. In yet another variation of the method, the organic acid comprises a group selected from monoarenes, oligoarenes and polyarenes.

In another variation of the method, the film comprises of nonconjugated groups having the formula, HD-L, where HD is a ‘head’ group and L is an organic or organometallic ligand. In particular aspect, HD is selected from the group consisting of phosphonic acid, sulfonic acid, carboxylic and boric acid. In one variation, each acid further comprising at least one organic ligand. In one variation, L is selected from the group consisting of alkyl, perfluoroalkyl, haloalkyl, alkenyl, alkoxy, aryl, aryloxy, heteroaryl and heteroaryloxy. In a particular variation, the organic acid is an aryl, arene or heteroaryl directly bonded to the acid. In another variation, the arenes of monoarenes, oligoarenes or polyarenes comprise a heteroatom. In a particular aspect, the arenes are thiophenes or anilines. As used herein, the “organic acid” that comprises the film comprise both the ligand and the acid group, including, for example, the phosphonic acid and the boronic acid groups.

In another aspect of the above method, the film comprises at least a portion of an interface between an electrode and an organic and/or inorganic charge transporting layer. In another variation, the method further comprises the step of adding an electron acceptor or an electron donor to the film to increase conductivity. In one aspect, the addition of an electron acceptor or an electron donor increases the structure to a semi-conducting state or a conducting state. In one variation, the electron acceptor is selected from the group consisting of tetracyanoquinodimethane and tetrafluorotetracyanoquinodimethane. A variety of electron acceptors or electron donors may be used as known in the art. Example of different classes of electron acceptors or electron donors that may be employed include metals, such as rubidium, sodium, etc.; metal halides, organometallics, or organics. As used herein, certain electron acceptors or electron donors may also be referred to as dopants. Non-limiting examples of organic electron acceptors include phthalocyanines, quinines, and metal complexes of phenylpyridines and phenylquinolines. Alternatively, the film may be ‘self-doped’ by application of electrical potential, light or heat. ‘Self-doped’ means a donor/acceptor pair is formed in the film, such as a self assembled monolayer.

In one another aspect, there is provided a film comprising at least one organic acid which modifies in at least one structure in an optical or electronic article one or more of: (a) the charge carrier injection barrier properties; (b) the charge conductivity properties; (c) the charge transport properties; (d) the work function properties; (e) the sub-threshold slope; and (f) the threshold voltage. In one variation of the above film, the acid is an organic acid residue. The change in the charge carrier injection barrier properties may be an increase or a decrease of greater than about 0 to about 2 eV or more. The change in the charge conductivity properties may constitute an increase in conductivity by up to seven orders of magnitude. The change in the charge transport properties may comprise a transition from hoping to band-like transport or resonant tunneling. The change in the work function properties may comprise an increase or a decrease of greater than 0 to about 2 eV or more.

In one variation, the film comprises at least a portion of an interface between two structures through which charge carriers are transported. In another variation, the film comprises at least a portion of an interface between an electrode and a charge carrier transporter.

In another aspect, there is provided an oxide surface comprising a film that comprises at least one organic acid residue covalently bound to the oxide surface, the film having a density which is substantially similar to that found in crystalline arrangement of the organic acid. In one variation of the oxide surface, the organic acid comprises a molecule selected from monoarenes, oligoarenes or polyarenes. In one aspect, the oxide surface is a substrate that is a metal, alloy or silicon substrate with native oxide overlayer formed on the substrate. In one aspect, the substrate is a metal selected form the group consisting of titanium, aluminum or iron, and their alloys. In one aspect, the titanium material substrate is bonded to a material selected from the group consisting of metal oxide, ceramic and polymers, or combination therein. In another aspect, the substrate is Si/SiO₂. In another aspect, the organic acid comprises of non-conjugated molecules, conjugated molecules or combinations thereof. In another aspect of the above, the organic acid is a self-assembled monolayer.

In yet another aspect, there is provided a film comprising a covalently bound organic acid residue, wherein the film forming a region of charge carrier conductivity between two structures in an article. In one variation, the film further comprises an electron acceptor or an electron donor selected from inorganic, organic or organometallic compounds. In one aspect, the electron acceptor or electron donor, or dopant, may comprise about 200 to 400 wt %, 100 to 200 wt %, 50 to 100 wt % or 10 to 50 wt %. In another aspect, the dopant may comprise about 2 to 10 wt %, 0.1 to 2 wt % or 0.0001 to 0.1 wt %.

In another variation of the film, the organic acid is a phosphonic acid comprising a saturated or an unsaturated organic ligand. In another variation, the unsaturated organic ligand is selected from monarenes, oligoarenes and polyarenes. In one aspect of the above film, the monoarenes, oligoarene and polyarene groups are thiophenes or anilines. In particular variations of the above, the monoarenes, oligoarene and polyarene groups may be unsubstitued or substituted. In another particular variation, the film that comprises a part of an electronic or optical article, and the film has conducting or semi-conducting properties. In a particular variation, the oligoarene group is selected from the group consisting of thiophene, bithiophene, terthiophene, tetrathiophene, sexithiophene, bianiline, tertaniline, tetraaniline, sexianiline, anthracene and pentacene.

In another aspect, there is provided an article having at least one structure which participates in at least one of charge carrier transport processes and/or charge carrier injection processes, the article comprising a structure therein having at least one electronic property selected from: (a) the charge carrier injection barrier properties; (b) the charge conductivity properties; (c) the charge transport properties; (d) the work function properties; (e) the sub-threshold slope; and (f) the threshold voltage altered by the above method. In one variation, the above structure has particular hole conduction properties. In another variation, the structure has particular electron conduction properties.

In another aspect, there is provided an article containing at least one structure participating in one or more of charge carrier transport processes and hole injection processes, wherein the structure is characterized by having an oxide surface or being in electronic communication with an oxide surface, and wherein the oxide surface has deposited on at least a portion thereof by a T-BAG method a film comprising at least one phosphonate moiety which thereby modifies at least one of the following properties of the structure: (a) the charge carrier injection barrier properties; (b) the charge conductivity properties; (c) the charge transport properties; (d) the work function properties; (e) the sub-threshold slope; and (f) the threshold voltage. In another aspect, there is provided a method of modifying the charge conductivity properties at the boundary region of at least one layer in a layered article, the layer being characterized as a layer which participates in at least one charge transfer process, the method comprising providing a film over at least a portion of the boundary region comprising at least one covalently bound phosphonate having an organic ligand. In one variation of the method, the film has conducting or semi-conducting properties. In another variation of the method, the organic ligand is an unsaturated hydrocarbon ligand or an unsaturated hydrocarbon containing a heteroatom ligand. In yet another variation of the method, the unsaturated hydrocarbon ligand or an unsaturated hydrocarbon containing a heteroatom is selected from a monoarene, oligoarene or polyarene. In one variation of the above method, the boundary region with improved charge carrier conductivity is in an electronic or optical article.

In yet another aspect, there is provided a layered article having at least one layer which participates in charge carrier transport processes, wherein at least one boundary region of at least one layer thereof has one or more of: (a) the charge carrier injection barrier properties; (b) the charge conductivity properties; (c) the charge transport properties; (d) the work function properties; (e) the sub-threshold slope; and (f) the threshold voltage of a layer thereof altered in accordance with the above method. In one variation, there is provided an article having one or more structures in accordance with the above structure which is selected from the group consisting of: (a) organic electronic and microelectronic articles; (b) molecular transistors and diodes; (c) polymer transistors and diodes; (d) organic, molecular, and polymer semiconducting devices; (e) photovoltaic devices; (f) sensors; and (g) memory devices.

In another aspect, there is provided an organic light emitting diode (LED) having an electrode, a hole transport layer, and residing at the interface therebetween, a film comprising at least one covalently bound organic acid residue having an unsaturated portion selected from monoarene, oligoarene and polyarene moieties. In another aspect, there is provided an organic light emitting diode (LED) having a transparent conductive oxide anode, a hole transport layer, and residing at the interface therebetween, a film comprising at least one covalently bound organic acid residue having an unsaturated portion selected from monoarene, oligoarene and polyarene moieties. In one aspect, the transparent conductive oxide is an indium tin oxide. In another aspect, the hole transport layer is a bis(naphthylphenylamine)diphenyl derivative.

In one variation of the above LED, the organic acid unsaturated portion is selected from bithiophene, terthiophene, tetrathiophene, sexithiophene, bianiline, tertaniline, tetraaniline, sexianiline, anthracene, and pentacene moieties. Optionally, each of the above moieties may be unsubstituted or substituted by one or more substituents. In another variation, the above LED further comprising an electron donor or electron acceptor.

In another aspect, there is provided a light emitting diode having a polymer hole transport layer or an electroluminescent layer which comprises an interface between the anode and hole transport layer comprising the film as described above. In another aspect, there is provided an organic field effect transistor (FET) having an organic semiconducting layer and comprising an interface between the organic semiconducting layer and an insulating layer comprising an oxide surface comprising a film that further comprises at least one organic acid residue covalently bound to the oxide surface, wherein the film comprises a phosphonate moiety bonded to the insulating layer and a ligand. In one variation of the FET, the insulating layer comprising an oxide surface is a dielectric surface. It is appreciated by one skilled in the art that dielectric materials may comprise of oxides on silicon, or a non-oxide containing surfaces such as certain polymers. In the case of non-oxide polymers, their surfaces can be oxidized by known methods in the art, such as by oxygen plasma or ultraviolet in air to form oxide surfaces. In a particular variation of the FET, the film has a density which is substantially similar to that found in crystalline arrangement of the organic acid. In another variation of the above FET, the film comprises a phosphonate moiety bonded to the insulating layer and a ligand. In one variation of the above film, the organic semiconducting layer comprises multiple layers of phosphonic acid moieties patterned on the film. In one aspect of the FET, the organic semiconducting layers are dense and oriented. In another variation of the FET, the multiple layers of phosphonic acid moieties patterned on the monolayer are provided by a single or repeated T-BAG depositions. In another variation, the multiple layers have crystalline structure. In yet another variation, the phosphonate moiety and the phosphonic acid moiety are derived from a phosphonic acid having a monoarene, oligoarene or polyarene moiety. In a particular aspect of the FET, the oligoarene or polyarene moiety is selected from bithiophene, terthiophene, tetrathiophene, sexithiophene, bianiline, tertaniline, tetraaniline, sexianiline, anthracene and pentacene moieties. Optionally, each of the above moieties may be unsubstituted or substituted by one or more substituents. In another aspect, there is provided a dense, oriented, monolayer film comprising at least one organic acid moiety having a phosphonate moiety bonded to a surface of a structure of an electronic or optical article, the organic acid moiety further comprises an oligoarene or polyarene portion. In one aspect, the organic acid moiety comprising a monoarene, oligoarene or polyarene portion is substantially perpendicular to the surface of the structure. In another aspect, the monoarene, oligoarene or polyarene portion further being substantially in alignment with an monoarene, oligoarene or polyarene portion of at least one proximal organic acid moiety.

In a particular variation of the above, the FET may comprise a “top” and “bottom” contact organic FETs. Top contact organic FETs are fabricated by depositing the source and drain metal on top of the (previously deposited) organic semiconductor layer. The metal may be patterned during deposition, such as through a stencil mask process, or by a post-deposition technique (such as lithography). Bottom contact organic FETs are fabricated by depositing the source/drain metal on the (oxide) dielectric, patterning the metal, and depositing the organic layer on top of the source/drain. In this case, the phosphonates may be added prior to, or post metal deposition. In another particular variation, of the above FETs, a silicon wafer is not employed as a gate. In such a case, a gate metal would be deposited (and patterned), followed by the deposition/patterning of the oxide gate dielectric, application of phosphonates, and either the top or bottom contact procedure as described above. In the above case, the substrate on which the gate/dielectric/phosphonate/source-drain/semiconductor are deposited can be any materials known in the art, including, for example, glass, plastics such as PET, PEN, or kapton, insulated metal substrates or any other reasonably flat surface.

In another aspect, there is provided an electronic article containing at least one structure having charge carrier transport properties which has one or more of: (a) the surface wettability properties; (b) the charge carrier injection properties; and (c) the charge conductivity properties of a structure therein altered by the provision of a covalently bound film comprising at least one organic acid moiety.

In a particular variation, there is provided a multi-layer film deposited upon a film as described above wherein the multi-layer film further characterized by being substantially crystalline. In one variation, the multi-layer further characterized in that it is deposited by repeated iteration of the method as described herein above. In the above aspects and variations, the film may be a self-assembled monolayer film. In another variation of the above, the electron acceptor is selected from the group consisting of tetracyanoquinodimethane and tetrafluorotetracyanoquinodimethane. In another aspect, the oligoarene or polyarene is selected from the group consisting of bithiophene, terthiophene, tetrathiophene, sexithiophene, bianiline, tertaniline, tetraaniline, sexianiline, anthracene, and pentacene moieties. Optionally, each of the above moieties may be unsubstituted or substituted by one or more substituents. In yet another aspect, the film is a dense and oriented monolayer.

According to the above structure, film, article, LED or FET of the present invention, the improvement in the charge carrier injection properties is by at least about 0.1 eV, preferably about 0.3 eV, more preferably about 0.5 eV more than the charge carrier injection properties of the structures not prepared accordingly to the method of the invention.

According to the above structure, film, article, LED or FET of the present invention, the improvement in the charge conductivity properties is by at least about two-fold, preferably at least by about 10-fold, more preferably at least by about 100-fold, and most preferably at least by about 1,000-fold than the charge conductivity properties of the structure, film, article, LED or FET not prepared accordingly to the invention.

According to the structure, film, article, LED or FET of the present invention, the improvement in the charge transport properties is by at least about two-fold, preferably at least by about 10-fold, more preferably at least by about 100-fold, and most preferably at least by about 1,000-fold than the charge transport properties of the structure, film, article, LED or FET not prepared accordingly to the invention.

According to the structure, film, article, LED or FET of the present invention, the improvement in the work function properties is about about 0.1 eV, preferably about 0.3 eV, more preferably about 0.5 eV more than the work function properties of the structure, film, article, LED or FET not prepared accordingly to the method of the invention.

All references cited herein are incorporated herein by reference in their entirety. As noted herein, it will be apparent to those skilled in the art that various modification and variation can be made in the methods, articles, structures and compositions of the present invention without departing from the spirit or scope of the invention. Therefore, it is intended that the present invention cover these various modifications and variations of this invention provided that the modifications and variations come within the scope of the following claims and their equivalents.

Experimental:

General. Bithiophene (2T; Aldrich) was used as received. THF (EM Science) was distilled over Na and stored under argon. Semiconductor grade single-crystal silicon (100) samples were cut from a single wafer into 8 mm×8 mm coupons. ITO-coated glass (Colorado Concepts) samples were cut into 20 mm×20 mm coupons. A 10 mm×20 mm strip of ITO was defined by covering the appropriate area with electrical tape and etching the surrounding ITO in 37% HCl; the tape was then removed. These samples were cleaned by hand polishing in a silica (grade 60, 230-400, Aldrich)/distilled water slurry for 30 seconds, rinsing in 1M NaOH (to remove remaining SiO₂) and distilled water. These polished samples were sonicated in detergent (2% Tergitol [Aldrich]/distilled water) for 20 minutes, rinsed with copious amounts of distilled water followed by sonication (10 minutes) and removal from boiling acetone. These samples were then further rinsed by boiling first in electronic grade isopropyl alcohol, then methylene chloride. Samples were dried under N₂ and used immediately. AFM analysis of films was done using a Digital Instruments Multimode Nanoscope IIIa SPM equipped with silicon tips (Nanodevices Metrology Probes; resonant frequency, 300 kHz; spring constant, 40 N/m) in tapping mode. Quartz crystal microbalance (QCM) measurements were made using a home-built Ward oscillator and 10 MHz, AT-cut quartz crystals (ICM) equipped with SiO₂/Si-coated (1000 Å Si/100 Å Cr/1000 Å Au undercoat) electrodes. IR spectra were obtained using a Midac Model 2510 spectrometer equipped with a Surface Optics Corp. specular reflectance attachment.

α-Quarterthiophene. α-Bithiophene (2T; 1.03 g; 6.2 mmol) was dissolved in a mixture of 20 mL of methanol and 20 mL of acetonitrile in a 50 mL three-necked flask. Distilled water (5 mL) was then added, and air was bubbled through the solution via a sparging tube. A condenser was fitted to the three-necked flask, and 190 mg of PdCl₂ (1.1 mmol; 0.18 equiv) was added slowly to the solution. The reaction mixture was stirred and was monitored by TLC (using 3:1 hexane:dichloromethane as eluant). As the reaction proceeded, α-quarterthiophene (4T) and Pd black precipitated, and some 2T was carried out of the reaction vessel by the air stream. When the supply of 2T was nearly exhausted (by TLC, after about 7 days), the reaction mixture was filtered; any unreacted α-bithiophene could be removed by washing the dark red precipitate with methanol. 4T was isolated as bright yellow crystals by sublimation (170° C., 1 mTorr; 480 mg, 1.45 mmol; 135% based on PdCl₂, 47% based on 2T; ¹H NMR [400 MHz, acetone-d₆]: [H2] 7.07-7.11, J_{HIH2}=5.2 Hz, J_{H2H3}=3.4 Hz; [H4, H5] 7.21-7.26, J_{H4H5}=3.5 Hz; [H3] 7.29-7.32, J_{H2H3}=3.3, J_{H1H3}=1.1 Hz; [H1] 7.42-7.46). The yield of 4T could be increased to 357% (based on PdCl₂) by addition of 1 equiv (based on Pd) of benzoquinone to assist in the reoxidation of Pd(0).

α-Quarterthiophene-2-(diethylphosphonate). Sublimed α-quarterthiophene (255.0 mg; 0.7727 mmol) was dissolved in 20 mL of dry, distilled THF, and the solution was cooled to −50° C. under dry N₂. A solution of n-butyllithium in hexane (Aldrich; 0.60 mL of a 2.5 M solution; 2 equiv) was added quickly via syringe, and the reaction mixture was allowed to stir at −50° C. for 2 h. Using 2 equiv of n-butyllithium is necessary because of the low solubility of 4T at −50° C. as compared with that of 2-lithioquarterthiophene; using 1 equiv of n-butyllithium gives 50% dilithiated 4T and 50% unreacted 2T. The color of the reaction mixture changed from chrome yellow to dark brown as lithiation proceeded. Diethyl chlorophosphate (0.135 mL; 1.2 equiv; Aldrich) was then added. The reaction mixture became dark orange and was allowed to stir at −50° C. for 2 h; it was then slowly warmed to room temperature and stirred for 8 h. The solvent was removed, and the resulting solid was extracted with methylene chloride. The product was separated by column chromatography (silica) using increasing proportions of ethyl acetate in hexane. Elution of a yellow solution with 40% ethyl acetate in hexane (the second yellow material eluted overall) yielded orange-brown α-quarterthiophene-2-(diethylphosphonate) (2) which was contaminated with a small amount of 4T (73 mg; 30%; ¹H NMR [acetone-d₆]: δ2.03 [m, —OCH₂CH₃, 6H], 4.05-4.18 [m, —OCH₂CH₃, 4H], 7.08-7.11 [dd, H8, J_{H8H9}=5.13 Hz, J_{H7H8}=3.63 Hz], 7.23-7.26 [d, H2, J_{H1H2}=3.87 Hz], 7.28-7.31 [dd, H5, H6, J_{H5H6}=2.14 Hz], 7.31-7.33 [dd, H7, J_{H7H9}=1.13 Hz], 7.37-7.42 [m, H3, H4], 7.44-7.47 [dd, H9], 7.52-7.57 [dd, H1, J_{H1P}=8.21 Hz]. ³¹p NMR: 610.7. HRMS: MW calc'd for C₂₀H₁₉O₃PS₄, 465.9955; found 465.9947). Ester 2 was hydrolyzed to 1 using 2 M HCl in ethanol at 70° C. for 3 days. The reaction mixture was cooled to 0° C. and centrifuged, and then triturated with cold methanol and dried in vacuo (1 mTorr) to give dark orange 4TPA (1; 62 mg; nearly quantitative). It was not possible to determine the critical micelle concentration for 1 because of its low solubility; a saturated solution of 1 in THF at room temperature is approximately 0.73 mM.

α-Quarterthiophene-2-phosphonate/SiO₂/Si. Yellow-green solutions of 4TPA were made by dilution of a stock solution of 4TPA in 50 mL of THF (0.73 mM, 15 mg). The diluted solutions (0.143 mM; 0.01 mM; 0.0025 mM) were then passed through a 0.2 μm PTFE syringe filter before use. Si samples were treated with the solutions of 4TPA as described above, except that heating was done under N₂ to prevent oxidation of the quarterthiophene moieties.

X-ray Reflectivity. X-ray experiments were done by Dr. Bert Nickel at the National Synchrotron Light Source (NSLS) using beam line X10b (Exxon) with wavelength λ=0.087 nm. Measurements were performed in reflectivity mode (v-2v), resulting in a momentum transfer, q_{z}, along the surface normal (q_{z}=4π/v sinv). A simple NaI detector was used, and receiving slit sizes within the scattering plane were 0.6 and 0.8 mm for sample and detector slit, respectively. Rocking scans were performed at different angles to verify the background level. The observed rocking width (fwhm) of these scans was resolution-limited to 0.03°. The background was kept low by side-ways clamping of the Si wafer substrates, which resulted in efficient isolation of the incident beam from any other material. Analyses of films of 4TP bonded to chemically reoxidized Si (HNO₃ oxidation of H-terminated Si; rms roughness 0.21 nm) were performed in air, and both rinsed and unrinsed samples of 4TP/SiO₂/Si were used. Data were analyzed using a freely available program based on the Parratt formalism (dynamical scattering). Various parametrizations for electron density profiles (n) were used to model reflectivity from the organic layer (slab profile with rounded edge and graded electron density profile).

Device fabrication. ITO-coated glass slides were cut into 20 mm×20 mm coupons. A 10 mm×20 mm strip of ITO was defined by covering the appropriate area with electrical tape and etching the surrounding ITO in 37% HCl. These samples were then rinsed as described above. Depositions of α-NPD, Alq₃ and Al layers were performed using a Edwards 306A thermal evaporation system at a base pressure of <10⁻⁶ mbar. α-NPD (Aldrich) was used as received and deposited at a rate of 2-3 Å/sec to a thickness of ca. 1500 Å. Aluminum (Alfa Aesar) contacts were defined by a shadow mask and deposited at a rate of ca. 12 Å/sec to a total thickness of ca. 750 Å. Device testing was accomplished using a Keithley 2400 Sourcemeter controlled by Labview software. Devices were cycled from 0 to 10 V until the I-V profile was unchanged by <5%. OLEDs were fabricated using the above procedure, except the organic layer was 500 Å α-NPD followed by 500 Å Alq3 and 750 Å Al.

OLED fabrication. OLEDs (ITO/500 Å α-NPD/500 Å Alq₃/5 Å LiF/500 Å Al) were fabricated using the above procedures for hole-only devices, using 500 Å α-NPD, and 500 Å Alq₃ at a deposition rate of 2 Å/sec as the organic layers, and 750 Å Al at a deposition rate of 12 Å/sec as the cathode material. A Hewlett-Packard 4145B semiconductor parameter analyzer with a Newport 1835-C optical power meter and a Newport model 818-UV silicon photodetector was used to measure J-V and L-V characteristics.

α-Quarterthiophene-2-phosphonic acid was prepared as previously described.⁴² Fluorimetry experiments were done by using a Photon Technology International Fluorescence Spectrometer. A Zeiss LSM 510 confocal fluorescence microscope was used for fluorescence imaging. Quartz crystal microgravimetric (QCM) measurements were made using a home-built Ward oscillator and ITO-electrode equipped crystals (10.000 MHz, AT-cut, 1000 Å ITO on 500 Å Al; International Crystal Manufacturing) which were used as received.

“T-BAG” preparation of α-quarterthiophene-2-phosphonate/ITO. Yellow-green solutions of α-quarterthiophene-2-phosphonic acid (4TPA) were made by dilution of a stock solution of 4TPA in 50 mL THF (0.73 mM, 15 mg), and diluted solutions were passed through a 0.2μ PTFE syringe filter before use. The monolayer film of α-quarterthiophene-2-phosphonate/ITO was prepared according to the “T-BAG” procedure⁴² as follows: ITO/glass coupons were held vertically using a small clamp in a solution of 4TPA in a 50 ml beaker. The solvent was allowed to evaporate slowly over 3 hrs, until the level of the solution fell below the glass coupon. Under these conditions, the concentration of the 4TPA in the remaining solution increased by about 30%. The treated ITO coupon was then removed from its holder and was heated at 140° C. in a simple glass tube under nitrogen for 2 days to bond the film to the ITO as α-quarterthiophene-2-phosphonate (4TP). Any multilayer 4TPA was removed by sonication in 5% triethylamine (Aldrich) in ethanol, typically for 30 min, followed by extensive rinsing with ethanol and then distilled/deionized water. Samples were then dried in a stream of dry N₂. It is important to note that extensive loss of surface phosphonate material occurs if coupons are carbonate-rinsed prior to heating.

Preparation and testing of hole-only and OLED devices. Depositions of N,N′-bis-(1-naphthyl)-N,N′-diphenyl-1,1-biphenyl-4,4′-diamine (99.9%; Aldrich; α-NPD), tris(8-hydroxy-quinoline)aluminum (99.995%, Aldrich; Alq3) and Al layers were performed using an Edwards 306A thermal evaporation system at a base pressure of <10⁻⁶ mbar. α-NPD was used as received and was deposited at a rate of 2-3 Å/sec to a thickness of ca. 1500 Å. Aluminum (Alfa Aesar) contacts were defined by a shadow mask and was deposited at a rate of ca. 12 Å/sec to a total thickness of ca. 750 Å. The overlap of the ITO stripe and Al contacts define the active device areas (ca. 4 mm² and 8 mm²). Hole-only device testing was accomplished using a Keithley 2400 Sourcemeter controlled by Labview software. All device characterization measurements were made under ambient conditions. Devices were cycled from 0 to 10 V until the I-V curves were reproducible within <5%. OLEDs were fabricated using a similar procedure to have 500 Å α-NPD, and 500 Å Alq3 deposited successively at rates of 2 Å/sec for each organic layer, and 750 Å Al deposited at a deposition rate of 12 Å/sec to serve as the cathode material. In addition, OLEDs equipped with LiF/Al cathodes were prepared (ITO/500 Å α-NPD/500 Å Alq3/5 Å LiF/500 Å Al). A Hewlett-Packard 4145B semiconductor parameter analyzer with a Newport 1835-C optical power meter and a Newport model 818-UV silicon photodetector was used to measure J-V and L-V characteristics.

General Materials and Procedures for PLED Experiments. Glass slides coated with indium tin oxide (Colorado Concept Coatings, 15 Ω/,O 1500A) were used after appropriate cutting and cleaning. 4TPA was prepared as described.⁴² F₄-TCNQ (Aldrich) and aluminum (Alfa Aesar) were used as received. Tetrahydrofuran (THF; EM Science) was distilled from Na and was stored under argon. An aqueous dispersion of PEDOT:PSS (Aldrich) was filtered through a 0.45 μm PES syringe filter (Whatman) immediately before use. Poly(2-methoxy-5-[2′-ethylhexyloxy]-p-phenylene vinylene) (MEH-PPV; Aldrich, Mn=150,000-250,000) was dissolved in chloroform and the solution was filtered though a 0.45 μm PTFE syringe filter (Acrodics) before use. The thickness of spin coated polymers was measured using a KLA-Tencor P15 Surface Profiler. Reflectance-absorbance infrared spectra were taken using a MIDAC FT-IR for 4TPA and 4TPA-F4-TCNQ-coated ITO; a blank ITO slide served as the background. XPS data were collected using a Phoibos 150 hemispherical energy analyzer (SPECS) and a monochromatized Al (1486.6 eV) source. A pass energy of 30 eV was used for wide range (survey) scans, while a 10 eV pass energy was used for high resolution measurements. For quantitative estimations of surface compositions standard atomic photoionization cross-section values from the SPECS database were used.

Pretreatment of the ITO: ITO-coated glass slides were cut into 20 min×20 min coupons. A 10 mm×20 min strip of ITO was defined by covering the appropriate area with electrical tape and etching the surrounding ITO in 37% HCl. The slides were then brushed with a soft toothbrush soaked with 2% aq. NP-10 Tergitol solution, then sonicated in the same solution following by rinsing away the foam. The slides then were rinsed again thoroughly with deionized water, rinsed with sonication for 5 min in acetone, submerged for 5 min in boiling acetone (3 cycles), submerged for 5 min in boiling isopropyl alcohol (3 cycles), and submerged for 5 min in boiling methylene chloride (3 cycles). They were then blown dry with N₂ and heated under N₂ at 100° C. for one hour, then stored in a holding chamber under vacuum (10-2 torr).

4TP/ITO: An ITO anode prepared as described above was clamped with an alligator clip and was dipped perpendicularly into a freshly prepared solution of 4TPA in THF (0. 1 uM). The THF was allowed to evaporate slowly to give a multilayer of the 4TPA on the ITO surface. The coated ITO was then heated for 48 hours under N₂ at 150° C., sonicated in a mixture of ethanol and 0. 5 M aq. K₂CO₃ (2:1), rinsed with distilled water, then blown dry with N₂ and then heated under N₂ for 10 min at 150° C. to give the bound monolayer of 4TP/ITO.

4TP-F4-TCNQ/ITO: A sample of 4TP/ITO was soaked in a solution of F4-TCNQ in methylene chloride (1 mM), then thoroughly rinsed with methylene chloride and blown dry with N₂ to give the title material.

PEDOT:PSS/ITO: An ITO sample cleaned as described above was spin-coated with a filtered aqueous solution of PEDOT:PSS at 2200 rpm. The resulting film was then cured in air at 150° C. for 20 min and was used immediately.

PLED Device Fabrication. Four different types of PLED devices were prepared with PEDOT:PSS/lTO, 4TP/ITO or 4TPA-F4-TCNQ/ITO and ITO used without any modification other than cleaning, as the control. For all devices, a 100 nm thick film of MEH-PPV was spin-coated onto the ITO from a chloroform solution and was annealed under vacuum (10⁻⁶ torr) for two hours. A 60 nm Al cathode was then thermo-evaporated on top of the MEH-PPV. The Al cathode was defined by a shadow mask and the overlap areas between both electrodes were measured to be 0.04 and 0.08 in², respectively. Device testing was done in air using a Keithley 2400 Sourcemeter controlled by Labview software. Devices were cycled from 0-8 V until the I-V profile was stable.

Quartz Crystal Microgravimetry measurements. ITO-electrode equipped quartz crystals (10.000 MHz, AT-cut, 1000 Å ITO on 500 Å Al) were obtained from International Crystal Manufacturing and were used as received. Quartz crystal microgravimetric (QCM) measurements were made using an ICM 35360 crystal oscillator powered by a Hewlett-Packard 6234A dual output power supply. The crystal frequency was measured using a Hewlett-Packard 53131A universal counter. In each experimental run, the fundamental frequency (fo) of an untreated QCM crystal was measured. Then a 0.1 μM solution of 4TP in THF was used to deposit SAMs of 4TP on both sides of the crystal by T-BAG; the crystals were then baked at 130° C. under N₂ for 90 min. Rinsing with THF, methanol and triethylamine (Acros) was done successively until the crystal frequency was unchanged. Repeated cycles of T-BAG, baking and rinsing were performed to ensure full coverage of the densely packed monolayer on the ITO electrode. Measuring identical frequency readings for two successive cycles was deemed to represent that point when the entire surface was fully covered. The frequency change from f₀, Δf=183±1 Hz, was used to calculate the surface loading.⁴²

X-Ray Photoelectron Spectra: XPS data were collected using a Phoibos 150 hemispherical energy analyzer (SPECS) and a monochromatized Al (1486.6 eV) source. A pass energy of 30 eV was used for wide range (survey) scans, while a 10 eV pass energy was used for high resolution measurements. For quantitative estimations of surface compositions standard atomic photo-ionization cross-section values from the SPECS database were used. All measurements were carried our at normal and grazing take-off angles. The sampling depth at normal take-off angle is considered to be 60-80 Å, while grazing angle measurements are more surface sensitive (sampling depth of about 20 Å).

Pentacene Transistors on 4TP SAM-Treated SiO₂ Surfaces:

Pentacene thin-film transistors (TFTs) were fabricated on 4TP SAM-treated SiO₂ and bare SiO₂ control substrates. In certain processes, the substrates were heavily doped Si wafers, covered with 3000 Å of thermal SiO₂. The doped Si acts as the transistor gate, and the SiO₂ serves as the gate dielectric. In certain cases, the dielectric is very thick (3000 Å) to reduce the number of pinholes, and increases the yield of the relatively large transistor structures. This thick dielectric layer will increase the voltages required for operation, however. In other examples, the dielectric is relatively thin (about 1000 Å or lower), and a decrease in the yield may be observed. The 4TP and control substrates were prepared using the same cleaning procedure: 3 min in boiling TCE, 3 min acetone, 3 min boiling methanol, blown dry with compressed air. In each deposition run, one 4TP sample and one control sample were placed side-by-side in a vacuum deposition system (base pressure 5×10⁻⁶ Torr) so that the deposition conditions were identical for both members of a 4TP/control pair. Pentacene was deposited through a shadow mask to a thickness of 500 Å at approximately 1 Å/s with the substrate at approximately 60° C. The patterning of the pentacene layer reduces leakage currents between adjacent transistors. Gold source and drain electrodes were deposited through a shadow mask to a thickness of 500 Å at approximately 1 Å/s with the substrate at (nominally) room temperature. Arrays of transistors were fabricated, with channel widths ranging from 0.5 to 1.5 mm, and channel lengths ranging from 25 μm to 250 μm, allowing study of transistors with a wide range of W/L ratios. Transistors were tested using two Keithley 237 Source Measure Units to apply source-gate and source-drain voltages, while simultaneously measuring gate and drain currents. The transistors were studied primarily in the saturation region of operation, by applying a large source-drain voltage (−50V typical), and sweeping the source-gate voltage from +50V (device off) to −50V (device on).

The control and 4TP-treated transistors appeared to have equal charge carrier (hole) mobilities, within experimental uncertainty, of at least about 0.4 cm/Vs, with many devices greater than 1 cm²/Vs. Note that the deposition conditions (1 Å/s @ 60° C. substrate temperature) is optimal for pentacene on bare SiO₂, and not necessarily so for the 4TP SAM samples. Deposition conditions may also be optimized for the treated samples according to the procedures as disclosed herein. Two striking improvements were noted in the 4TP treated samples: 1) improvement in the sub-threshold slope, and 2) reduction in the threshold voltage.

1) Sub-threshold slope: For application of the transistors, the “on” and “off” currents may differ by many orders of magnitude (approx. 5-6, minimum). Sub-threshold slope is a measure of how easily the transistor current can reduced to negligible amounts, by the application of the appropriate gate bias (+ve bias in p-type devices, such as these). The sub-threshold slope is expressed in V/decade of current, and may be determined by the number of volts that must be applied apply to the gate in order to reduce the transistor current by an order of magnitude. This is an important measure, as it dictates the amount of voltage swing, and therefore power, that a circuit must supply to the device. Ideally, the lower limit of the sub-threshold slope is dictated by Boltzmann (the Fermi-Dirac) statistics, which describes the change in the charge carrier density with Fermi level position. At room temperature, this limit is ΔV/k_{B}T=+ln(10), or approximately 57 mV/decade. This is independent of the gate dielectric thickness. However, the movement of the Fermi level is hindered by charge-trapping states at the semiconductor/dielectric interface, or in the dielectric itself. Thus more voltage swing is required to populate/depopulate these states. It is noted that this does depend on the dielectric thickness, as the trapped charge/dielectric/gate now acts as a capacitor. The thicker the dielectric, the larger the voltage swing that is required to move the Fermi energy a given amount. Note that our thick gate dielectric makes these voltages large. It is the effect caused by the addition of 4TP that is important.

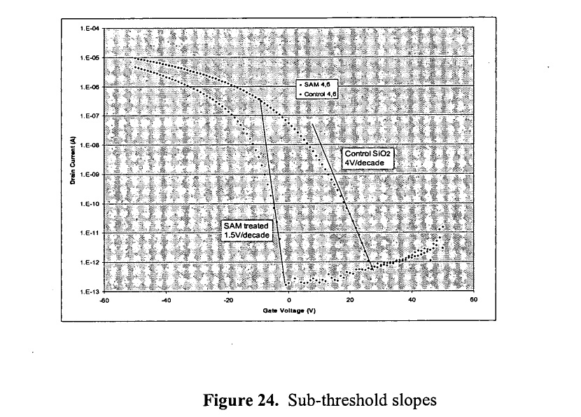

In these experiments, there was a clear improvement in the sub-threshold slope exhibited by 4TP-treated samples. The 4TP samples were found to uniformly have a slope of 1.5V/decade, compared to approx 4V/decade for the control devices (FIG. 24). The value of 1.5V/decade is vastly superior than those reported in the art (U.S. Pat. No. 6,433,359 B1); and the improvement is even more pronounced considering the dielectric constant of alumina and the thickness of 1,500 Å versus using SiO₂ with dielectric constant of 3.9 with a thickness of 3,000 Å. As noted, higher dielectric constant materials and thinner dielectric should improve the subthreshold slope. Therefore, this result demonstrates that 4TP is clearly superior over those reported in the art. On/off ratios of the 4TP samples were determined to be between 10⁷ and 10⁸.

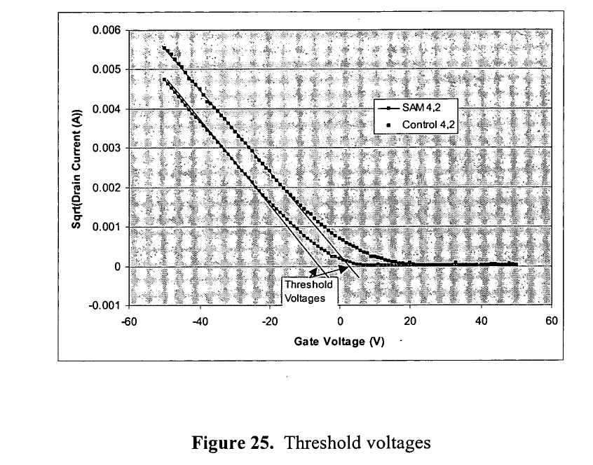

2) Threshold voltage: Threshold voltages are also important. For p-channel devices, it is usually advantageous to have a slightly negative threshold voltage, so that the current through the device is nearly zero with zero gate voltage, and so that the total voltage swing/power required to turn the device on and off is reduced. Threshold voltages are typically determined by the dielectric/semiconductor interfacial charge trap density, much as the sub-threshold slope. The 4TP treated samples showed a slightly negative, near-zero threshold voltage (FIG. 25). The 4TP treated samples have the desired threshold voltages and that are smaller than controlled devices with near zero and show less scatter than those in the art (U.S. Pat. No. 6,433,359 B1). This demonstrate that the 4TP structure allow the tuning of the threshold voltage to a desired voltage range. Note that both this result, and the improved sub-threshold slope are consistent with a reduction in dielectric/semiconductor interfacial charge trapping states.

### REFERENCES

1. Conjugated Polymer and Molecular Interfaces: Science and Technology for Photonic and Optoelectronic Applications; Salaneck, W. R.; Seki, K.; Kahn, A.; Pireaux, J.-J., Eds.; Marcel Dekker: New York, 2001.
2. Campbell, I. H.; Kress, J. D.; Martin, R. L.; Smith, D. L.; Barashkov, N. N.; Ferraris, J. P. Appl. Phys. Lett. 1997, 71, 3528.
3. Zuppiroli, L.; Si-Ahmed, L.; Kamaras, K.; Nüesch, F.; Bussac, M. N.; Ades, D.; Siove, A. Eur. Phys. J. B 1999,11, 505.
4. Appleyard, S. F. J.; Willis, M. R. Opt. Mater. 1998, 9, 120.
5. Yan, H.; Huang, Q.; Cui, J.; Veinot, G. C.; Kern, M. M.; Marks, T. J. Adv. Mater. 2003, 15, 835.
6. Morgado, J.; Charas, A.; Barbagallo, N. Appl. Phys. Lett. 2002, 81, 933.
7. Appleyard, S. F. J.; Day, S. R.; Pickford, R. D.; Willis, M. R. J. Mater. Chem. 2000, 10, 169.
8. Cui, J.; Huang, Q. L.; Veinot, J. G. C.; Yan, H.; Marks, T. J. Advanced Materials 2002, 14, 565.
9. Hatton, R. A.; Willis, M. R.; Chesters, M. A.; Rutten, F. J. M.; Briggs, D. Journal of Materials Chemistry 2003, 13, 38.
10. Ho, P. K. H.; Granström, M.; Friend, R. H.; Greenham, N. C. Adv. Mater. 1998, 10, 769.
11. Nüesch, F.; Rotzinger, F.; Si-Ahmed, L.; Zuppiroli, L. Chem. Phys. Lett. 1998, 288, 861.
12. Guo, J.; Koch, N.; Schwartz, J. Bemasek, S. L. J. Phys. Chem. B 2005, 109, 3966.
13. Ishii, H.; Sugiyama, K.; Ito, E.; Seki, K. Adv. Mater. 1999, 11, 605.
14. Christmann, K. Introduction to Surface Physical Chemistry; Springer-Verlag: New York, 1991.
15. Bruner, E. L.; Koch, N.; Span, A. R.; Bernasek, S. L.; Kahn, A.; Schwartz, J. J. Am. Chem. Soc. 2002, 124, 3192.
16. Bruening, M.; Moons, E.; Yaron-Marcovich, D.; Cahen, D.; Libman, J.; Shanzer, A. J. Am. Chem. Soc. 1994, 116, 2972.
17. Cui, J.; Huang, Q. L.; Wang, Q. W.; Marks, T. J. Langmuir 2001, 17, 2051.
18. Gao, W.; Kahn, A. J. Appl. Phys. 2003, 94, 359.
19. Zhou, X.; Pfeiffer, M.; Blochwitz, J.; Werner, A.; Nollau, A.; Fritz, T.; Leo, K. Appl. Phys. Lett. 2001, 78, 410.
20. Hatton, R. A.; Day, S. R.; Chesters, M. A.; Willis, M. R. Thin Solid Films 2001, 394, 292.
21. Dimitrakopoulos, C. D.; Malenfant, P. R. L., Organic thin film transistors for large area electronics. Advanced Materials 2002, 14, 99-114.
22. Dimitrakopoulos, C. D.; Mascaro, D. J., Organic Thin-Film Transistors: A Review of Recent Advances. IBMJ Res. Dev. 2001, 45, 11-27.
23. Chwang, A. B.; Frisbie, C. D., Field effect transport measurements on single grains of sexithiophene: Role of the contacts. Journal of Physical Chemistry B 2000, 104, 12202-12209.
24. Horowitz, G., Organic field-effect transistors. Advanced Materials 1998, 10, 365-377.
25. Akimichi, H.; Waragai, K.; Hotta, S.; Kano, H.; Sakaki, H., Field-Effect Transistors Using Alkyl Substituted Oligothiophenes. Applied Physics Letters 1991, 58, 1500-1502.
26. Horowitz, G.; Hajlaoui, M. E., Grain size dependent mobility in polycrystalline organic field-effect transistors. Synthetic Metals 2001, 122, 185-189.
27. Granstrom, E. L.; Frisbie, C. D., Field effect conductance measurements on thin crystals of sexithiophene. Journal of Physical Chemistry B 1999, 103, 8842-8849.
28. Ruiz, R.; Nickel, B.; Koch, N.; Feldman, L. C.; Haglund, R. F.; Kahn, A.; Family, F.; Scoles, G., Dynamic scaling, island size distribution, and morphology in the aggregation regime of submonolayer pentacene films. Physical Review Letters 2003, 91,136102-1-136102-4.
29. Torsi, L.; Dodabalapur, A.; Rothberg, L. J.; Fung, A. W. P.; Katz, H. E., Intrinsic transport properties and performance limits of organic field-effect transistors. Science 1996, 272, 1462-1464.
30. Bredas, J. L.; Calbert, J. P.; da Silva, D. A.; Cornil, J., Organic semiconductors: A theoretical characterization of the basic parameters governing charge transport. Proceedings of the National Academy of Sciences of the United States of America 2002, 99, 5804-5809.
31. Buzhansky, L.; Feit, B. A., A novel approach to a one-pot synthesis of unsubstituted oligo(alpha-thiophenes). Journal of Organic Chemistry 2002, 67, 7523-7525.
32. Melucci, M.; Barbarella, G.; Sotgiu, G., Solvent-free, microwave-assisted synthesis of thiophene oligomers via Suzuki coupling. Journal of Organic Chemistry 2002, 67, 8877-8884.
33. Bauerle, P.; Wurthner, F.; Gotz, G.; Effenberger, F., Selective Synthesis of Alpha-Substituted Oligothiophenes. Synthesis-Stuttgart 1993, 1099-1103.
34. Barbarella, G.; Zambianchi, M.; Sotgiu, G.; Bongini, A., Improved synthesis of functionalized sexithiophenes. Tetrahedron 1997, 53, 9401-9406.
35. Katz, H. E.; Torsi, L.; Dodabalapur, A., Synthesis, material properties, and transistor performance of highly pure thiophene oligomers. Chemistry of Materials 1995, 7, 2235-2241.
36. Bozell, J. J.; Hegedus, L. S., Palladium-Assisted Functionalization of Olefins—a New Amination of Electron-Deficient Olefins. Journal of Organic Chemistry 1981, 46, 2561-2563.
37. Hanson, E. L.; Schwartz, J.; Nickel, B.; Koch, N.; Danisman, M. F., Bonding self-assembled, compact organophosphonate monolayers to the native oxide surface of silicon. Journal of the American Chemical Society 2003, 125, 16074-16080.
38. Azzam, W.; Wehner, B. I.; Fischer, R. A.; Terfort, A.; Woll, C., Bonding and orientation in self-assembled monolayers of oligophenyldithiols on Au substrates. Langmuir 2002, 18, 7766-7769.
39. Sassella, A.; Besana, D.; Borghesi, A.; Campione, M.; Tavazzi, S.; Lotz, B.; Thierry, A., Crystal structure of polycrystalline films of quaterthiophene grown by organic molecular beam deposition. Synthetic Metals 2003, 138, 125-130.
40. Kagan, C. R.; Afzali, A.; Martel, R.; Gignac, L. M.; Solomon, P. M.; Schrott, A. G.; Ek, B., Evaluations and considerations for self-assembled monolayer field-effect transistors. Nano Letters 2003, 3, 119-124.
41. Frey, B. L.; Hanken, D. G.; Corn, R. M., Vibrational Spectroscopic Studies of the Attachment Chemistry for Zirconium Phosphonate Multilayers at Gold and Germanium Surfaces. Langmuir 1993, 9, 1815-1820.
42. Hanson, E. L.; Schwartz, J.; Nickel, B.; Koch, N.; Danisman, M. F., Bonding self-assembled, compact organophosphonate monolayers to the native oxide surface of silicon. Journal of the American Chemical Society 2003, 125, 16074-16080.
43. Midwood, K.; Carolus, M. D.; Danahy, M. P.; Schwarzbauer, J.; Schwartz, J. Langmuir 2004,20,5501.
44. Danahy, M. P.; Avaltroni, M. J.; Midwood, K.; Schwarzbauer, J.; Schwartz, J. Langmuir 2004, 20, 5333.
45. Purvis, K. L.; Lu, G.; Schwartz, J.; Bernasek, S. L. J. Am. Chem. Soc. 2000, 122, 1808.
46. Sassella, A.; Besana, D.; Borghesi, A.; Campione, M.; Tavazzi, S.; Lotz, B.; Thierry, A. Synth. Met. 2003, 138, 1.
47. Bredas, J. L.; Calbert, J. P.; da Silva, D. A.; Cornil, J. Proc. Nat. Acad. Sci. 2002, 99, 5804.
48. Yonezawa, Y.; Mobius, D.; Kuhn, H. J. Appl. Phys. 1987, 62, 2022.
49. Hotta, S.; Waragai, K. Synth. Met. 1989, 32, 395.
50. Brocks, G. Phys. Rev. B 1997, 55, 6816.
51. Koch, N.; Pascal Jr., R. A., unpublished results.
52. Heil, H.; Steiger, J.; Karg, S.; Gastel, M.; Ortner, H.; von Seggem, H. J. Appl. Phys. 2001, 89, 420.
53. Scott, J. C.; Malliaras, G. G.; Chen, W. D.; Breach, J. C.; Salem, J. R.; Brock, P. J.; Sachs, S. B.; Chidsey, C. E. D., Hole limited recombination in polymer light-emitting diodes. Applied Physics Letters 1999, 74, 1510-1512.
54. Horowitz, G.; Hajlaoui, M. E., Grain size dependent mobility in polycrystalline organic field-effect transistors. Synthetic Metals 2001, 122, 185-189.
55. Ruiz, R.; Nickel, B.; Koch, N.; Feldman, L. C.; Haglund, R. F.; Kahn, A.; Family, F.; Scoles, G., Dynamic scaling, island size distribution, and morphology in the aggregation regime of submonolayer pentacene films. Physical Review Letters 2003, 91. 136102-1-136102-4
b 56. Vuillaume, D., Nanometer-scale organic thin film transistors from self-assembled monolayers. Journal of Nanoscience and Nanotechnology 2002, 2, 267-279.
57. Yang, X. H.; Mo, Y. Q.; Yang, W.; Yu, G.; Cao, Y., Efficient polymer light emitting diodes with metal fluoride/Al cathodes. Applied Physics Letters 2001, 79, 563-565.
58. Carter, S. A.; Angelopoulos, M.; Karg, S.; Brock, P. J.; Scott, J. C., Polymeric anodes for improved polymer light-emitting diode performance. Applied Physics Letters 1997, 70, 2067-2069.
59. de Jong, M. P.; van Ijzendoorn, L. J.; de Voigt, M. J. A., Stability of the interface between indium-tin-oxide and poly(3,4-ethylenedioxythiophene)/poly(styrenesulfonate) in polymer light-emitting diodes. Applied Physics Letters 2000, 77, 2255-2257.
60. Malliaras, G. G.; Scott, J. C., The roles of injection and mobility in organic light emitting diodes. Journal of Applied Physics 1998, 83, 5399-5403.

1. A structure comprising a substrate coated by an organic acid that modifies one or more of the following: (a) the charge carrier injection barrier properties; (b) the charge conductivity properties; (c) the charge transport properties; (d) the work function properties; (e) the sub-threshold slope; and (f) the threshold voltage.

2. The structure of claim 1 wherein the organic acid is selected from the group consisting of a monothiophene acid, oligothiophene acid and polythiophene acid.

3. The structure of claim 2 wherein the organic acid is a monothiophene, oligothiophene or polythiophene phosphonic acid.

4. The structure of claim 1 further comprising an electron acceptor or an electron donor.

5. The structure of claim 1 wherein the organic acid is covalently bonded to the substrate.

6. The structure of claim 4 wherein the electron acceptor is TCNQ.

7. The structure of claim 5 wherein at least one of the properties comprising (a) the charge carrier injection barrier properties are improved by at least about 0.1 eV; (b) the charge conductivity properties are improved by at least about two-fold; (c) the charge transport properties are improved by at least about two-fold; (d) the work function properties are improved by at least about 0.1 eV; (e) the sub-threshold slope is improved by at least about 10%; and (f) the threshold voltage is changed by at least about 10%.

8. A method for altering an electronic property of a structure comprising an oxide surface or an oxide surface in electronic communication with the structure, the method comprising providing a covalently-bound film comprising at least one organic acid residue on a portion of the oxide surface so that at least one of the following properties of the structure is modified: (a) the charge carrier injection barrier properties; (b) the charge conductivity properties; (c) the charge transport properties; (d) the work function properties; (e) the sub-threshold slope; and (f) the threshold voltage.

9. The method of claim 8, wherein the organic acid is a phosphonic acid.

10. The method of claim 8, wherein the structure is in an electronic or optical article, and the film has conducting or semi-conducting properties.

11. The method of claim 8 wherein the film comprises at least a portion of an interface through which charge carriers are transported.

12. The method of claim 8 wherein the organic acid comprises a group selected from monoarenes, oligoarenes and polyarenes.

13. The method of claim 8, wherein the film comprises of nonconjugated group having the formula, HD-L, where HD is a ‘head’ group and L is an organic or organometallic ligand.

14. The method of claim 13, wherein HD is selected from the group consisting of phosphonic acid, sulfonic acid, carboxylic and boronic acid.

15. The method of claim 14, wherein L is selected from the group consisting of alkyl, perfluoroalkyl, haloalkyl, alkenyl, alkoxy, aryl, aryloxy, heteroaryl and heteroaryloxy.

16. The method of claim 12 wherein the arenes of monoarenes, oligoarenes or polyarenes comprises a heteroatom.

17. The method of claim 8 wherein the film comprises at least a portion of an interface between an electrode and an organic and/or inorganic charge transporting layer.

18. The method of claim 8 further comprising the step of adding an electron acceptor or an electron donor to the film to increase conductivity.

19. The method of claim 18 wherein the electron acceptor is selected from the group consisting of tetracyanoquinodimethane and tetrafluorotetracyanoquinodimethane.

20. A film comprising at least one organic acid which modifies in at least one structure in an optical or electronic article one or more of: (a) the charge carrier injection barrier properties; (b) the charge conductivity properties; (c) the charge transport properties; (d) the work function properties; (e) the sub-threshold slope; and (f) the threshold voltage.

21. The film of claim 20 which comprises at least a portion of an interface between two structures through which charge carriers are transported.

22. The film of claim 20 which comprises at least a portion of an interface between an electrode and a charge carrier transporter.

23. An oxide surface comprising a film that comprises at least one organic acid residue covalently bound to the oxide surface, the film having a density which is substantially similar to that found in crystalline arrangement of the organic acid.

24. The oxide surface of claim 23, wherein the organic acid comprises a molecule selected from monoarenes, oligoarenes or polyarenes.

25. A film comprising a covalently bound organic acid residue, wherein the film forming a region of charge carrier conductivity between two structures in an article.

26. The film of claim 25 further comprising an electron acceptor or an electron donor selected from inorganic, organic or organometallic compounds.

27. The film of claim 25, wherein the organic acid is a phosphonic acid comprising a saturated or an unsaturated organic ligand.

28. The film of claim 27 wherein the unsaturated organic ligand is selected from monoarenes, oligoarenes and polyarenes.

29. The film of claim 25 that comprises a part of an electronic or optical article, and the film has conducting or semi-conducting properties.

30. The film of claim 28 wherein the oligoarene group is selected from the group consisting of bithiophene, terthiophene, tetrathiophene, sexithiophene, bianiline, tertaniline, tetraaniline, sexianiline, anthracene and pentacene.

31. An article having at least one structure which participates in at least one of charge carrier transport processes and/or charge carrier injection processes, the article comprising a structure therein having at least one electronic property selected from: (a) the charge carrier injection barrier properties; (b) the charge conductivity properties; (c) the charge transport properties; (d) the work function properties; (e) the sub-threshold slope; and (f) the threshold voltage altered by the method of claim 8.

32. An article containing at least one structure participating in one or more of charge carrier transport processes and hole injection processes, wherein the structure is characterized by having an oxide surface or being in electronic communication with an oxide surface, and wherein the oxide surface has deposited on at least a portion thereof by a T-BAG method a film comprising at least one phosphonate moiety which thereby modifies at least one of the following properties of the structure: (a) the charge carrier injection barrier properties; (b) the charge conductivity properties; (c) the charge transport properties; and (d) the work function properties.

33. A method of modifying the charge conductivity properties at the boundary region of at least one layer in a layered article, the layer being characterized as a layer which participates in at least one charge transfer process, the method comprising providing a film over at least a portion of the boundary region comprising at least one covalently bound phosphonate having an organic ligand.

34. The method of claim 33 wherein the film has conducting or semi-conducting properties.

35. The method of claim 33 wherein the organic ligand is an unsaturated hydrocarbon ligand or an unsaturated hydrocarbon containing a heteroatom ligand.

36. The method of claim 35 wherein the unsaturated hydrocarbon ligand or an unsaturated hydrocarbon containing a heteroatom is selected from a monoarene, oligoarene or polyarene.

37. The method of claim 33 wherein the boundary region with improved charge carrier conductivity is in an electronic or optical article.

38. A layered article having at least one layer which participates in charge carrier transport processes, wherein at least one boundary region of at least one layer thereof has one or more of: (a) the charge carrier injection barrier properties; (b) the charge conductivity properties; (c) the charge transport properties; (d) the work function properties; (e) the sub-threshold slope; and (f) the threshold voltage of a layer thereof altered in accordance with the method of claim 33.

39. An article having one or more structures in accordance with claim 18 which is selected from the group consisting of: (a) organic electronic and microelectronic articles; (b) molecular transistors and diodes; (c) polymer transistors and diodes; (d) organic, molecular, and polymer semiconducting devices; (e) photovoltaic devices; (f) sensors; and (g) memory devices.

40. An organic light emitting diode (LED) having an electrode, a hole transport layer, and residing at the interface therebetween, a film comprising at least one covalently bound organic acid residue having an unsaturated portion selected from monoarene, oligoarene and polyarene moieties.

41. The LED of claim 40 wherein the organic acid unsaturated portion is selected from thiophene, bithiophene, terthiophene, tetrathiophene, sexithiophene, bianiline, tertaniline, tetraaniline, sexianiline, anthracene and pentacene moieties.

42. The LED of claim 40 further comprising an electron donor or electron acceptor.

43. A light emitting diode having a polymer hole transport layer or an electroluminescent layer which comprises an interface between the anode and hole transport layer comprising the film according to claim 25.

44. An organic field effect transistor (FET) having an organic semiconducting layer and comprising an interface between the organic semiconducting layer and a dielectric surface comprising a film that further comprises at least one organic acid residue covalently bound to the oxide surface, wherein the film comprises a phosphonate moiety bonded to the insulating layer and a ligand.

45. The organic field effect transitor of claim 44, wherein the film has a density which is substantially similar to that found in crystalline arrangement of the organic acid.

46. The FET of claim 44 wherein the organic semiconducting layer comprises multiple layers of phosphonic acid moieties patterned on the film.

47. The FET of claim 46 wherein the multiple layers of phosphonic acid moieties patterned on the monolayer are provided by single or repeated T-BAG depositions.

48. The FET of claim 46 wherein the multiple layers have crystalline structure.

49. The FET of claim 46 wherein the phosphonate moiety and the phosphonic acid moiety are derived from a phosphonic acid having a monoarene, oligoarene or polyarene moiety.

50. An electronic article containing at least one structure having charge carrier transport properties which has one or more of: (a) the surface wettability properties; (b) the charge carrier injection properties; (c) the charge conductivity properties of a structure therein altered by the provision of a covalently bound film comprising at least one organic acid moiety.

51. A multi-layer film deposited upon a film of claim 8, the multi-layer film further characterized by being substantially crystalline.

52. The multi-layer of claim 51 further characterized in that it is deposited by repeated iteration of the method of claim 8.
